(19) United States
(12) Patent Application Publication
(10) Pub. No.: US 2013/0245975 A1
(43) Pub. Date: Sep. 19, 2013

(54) DRAWING DEVICE, DRAWING METHOD, AND COMPUTER-READABLE RECORDING MEDIUM

(71) Applicant: FUJITSU LIMITED, Kawasaki-shi (JP)

(72) Inventors: Takashi KOBAYASHI, Machida (JP); Mitsunobu OKANO, Kawasaki (JP); Shogo FUJIMORI, Yamato (JP); Hiroyuki ORIHARA, Sumida (JP)

(73) Assignee: FUJITSU LIMITED, Kawasaki-shi (JP)

(21) Appl. No.: 13/720,389

(22) Filed: Dec. 19, 2012

(30) Foreign Application Priority Data
Mar. 19, 2012 (JP) 2012-062772

(51) Int. Cl. G01R 19/00

(52) U.S. Cl. CPC G01R 19/0084
USPC 702/64

(57) ABSTRACT

A drawing device includes a memory and a processor coupled to the memory. The processor executes a process including measuring voltages of planes of layers in a laminated circuit board and drawing the voltages of the planes that are measured on a graph having a voltage set on one axis and having a layer set on the other axis.

### CROSS-REFERENCE TO RELATED APPLICATIONS

This application is based upon and claims the benefit of priority of the prior Japanese Patent Application No. 2012-062772, filed on Mar. 19, 2012, the entire contents of which are incorporated herein by reference.

### FIELD

The embodiments discussed herein are related to a drawing device, a drawing method, and drawing program.

### BACKGROUND

In an electric circuit that is disposed on a laminated circuit board such as a printed circuit board, in a case where power is supplied from a power supplying component such as a power supplying pin to an integrated circuit, a voltage drop occurs due to the resistance of a conductive body such as a plane or a via. Since a voltage of a predetermined level or higher is used so as to operate an integrated circuit, for example, a large scale integration (LSI), the voltage drop is calculated through an analysis or the like, and it is verified whether or not a voltage applied to the LSI satisfies a voltage value used for operating the LSI. This verification may be performed by a person. Thus, there is a technology for processing the appearance of the voltage drop that is calculated through an analysis or the like into a form that can be perceived by a person and displaying the processed appearance of the voltage drop.

For example, there is a technology in which an image, in which voltages calculated by an analysis are represented in colors corresponding to the voltages, is two-dimensionally or three-dimensionally displayed as the appearance of a voltage drop when seen in the Z axis direction in a laminated circuit board. In addition, there is a technology in which an image represented by colors or thicknesses of lines corresponding to the amounts of currents is two-dimensionally or three-dimensionally displayed as the appearance of a flowing current when seen in the Z axis direction in a laminated circuit board.
Patent Document 1: Japanese Laid-open Patent Publication No. 2002-203001
Patent Document 2: Japanese Laid-open Patent Publication No. 2004-199279

However, according to the conventional technologies described above, there is a problem in that it is difficult to perceive the appearance of a voltage drop in the laminated circuit board in an easy manner.

For example, according to the technology in which an image, in which voltages calculated by an analysis are represented in colors corresponding to the voltages, is two-dimensionally displayed as the appearance of a voltage drop when seen in the Z axis direction in a laminated circuit board, the voltage drop in a plane of a specific layer is two-dimensionally displayed. Accordingly, it is difficult to perceive the appearance of a voltage drop in the entire laminated circuit board from the two-dimensional image. In addition, since the plane and a via intersect each other, it is difficult to perceive a voltage drop in the Z axis direction, that is, the direction of the via from the display of the appearance of a voltage drop in the plane of the specific layer.

In addition, according to the technology in which an image, in which voltages calculated by an analysis are represented in colors corresponding to the voltages, is three-dimensionally displayed, the size of a via that is displayed is smaller than the size of the plane. In addition, since there is an overlap between displays of the via and the plane, it is difficult to perceive the via that is relatively small unless it is displayed in an enlarged scale. According to the technology in which the appearance of a voltage effect is three-dimensionally displayed, in order to perceive a voltage drop in the entire laminated circuit board, a movement of a portion to be displayed and the scaling of a display are repeatedly performed. Accordingly, it is difficult to perceive the appearance of the voltage drop in the entire laminated circuit board in an easy manner.

### SUMMARY

According to an aspect of an embodiment, a drawing device includes a memory and a processor coupled to the memory. The processor executes a process including measuring voltages of planes of layers in a laminated circuit board and drawing the voltages of the planes that are measured on a graph having a voltage set on one axis and having a layer set on the other axis.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram that illustrates an example of the functional configuration of a drawing device according to a first embodiment;

FIG. 2 is a diagram that illustrates an example of the data structure of first CAD data;

FIG. 3 is a diagram that illustrates an example of the data structure of second CAD data;

FIG. 4 is a schematic diagram of a laminated circuit board;

FIG. 5 is a diagram that illustrates an example of the data structure of a measurement point table;

FIG. 6 is a diagram that illustrates an example of the data structure of a connection table;

FIG. 7 is a diagram that illustrates an example of the process of recording various kinds of information in the measurement point table;

FIG. 8 is a diagram that illustrates an example of the process of recording various kinds of information in the measurement point table;

FIG. 9 is a diagram that illustrates an example of the process for recording various kinds of information in the connection table;

FIG. 10 is a diagram that illustrates an example of the process for recording various kinds of information in the connection table;

FIG. 11 is a diagram that illustrates an example of the measurement point table in which various kinds of information are recorded by a recording unit;

FIG. 12 is a diagram that illustrates an example of the X axis and the Y axis that are drawn by a drawing unit;

FIG. 13 is a diagram that illustrates an example of a segment formed by a minimal voltage and a maximal voltage of each plane that is drawn by the drawing unit;

FIG. 14 is a diagram that illustrates an example of a segment representing a voltage drop of a via that is drawn by the drawing unit;

FIG. 15 is a diagram that illustrates the correspondence relation between a generated graph and a plane, a via, a power supplying pin, and a power consuming pin of the laminated circuit board;

FIG. 16 is a flowchart that illustrates the sequence of a drawing process according to the first embodiment;

FIG. 17 is a flowchart that illustrates the sequence of a recording process according to the first embodiment;

FIG. 18 is a flowchart that illustrates the sequence of the recording process according to the first embodiment;

FIG. 19 is a flowchart that illustrates the sequence of a measurement process according to the first embodiment;

FIG. 20 is a flowchart that illustrates the sequence of a coordinate-axis drawing process according to the first embodiment;

FIG. 21 is a flowchart that illustrates the sequence of a plane voltage drop drawing process according to the first embodiment;

FIG. 22 is a flowchart that illustrates the sequence of a via voltage drop drawing process according to the first embodiment;

FIG. 23 is a diagram that illustrates an example of the functional configuration of a drawing device according to a second embodiment;

FIG. 24 is a diagram that illustrates an example of the data structure of a connection table according to the second embodiment;

FIG. 25 is a diagram that illustrates an example of a segment that represents the magnitude of a current flowing through a via that is drawn by a drawing unit;

FIG. 26 is a flowchart that illustrates the sequence of a measurement process according to the second embodiment;

FIG. 27 is a flowchart that illustrates the sequence of a via voltage drop drawing process according to the second embodiment;

FIG. 28 is a schematic diagram of a laminated circuit board in a case where there is a plurality of paths connecting two points in a net and the paths go through planes that are different from each other;

FIG. 29 is a diagram that illustrates an example of the functional configuration of a drawing device according to a third embodiment;

FIG. 30 is a diagram that illustrates an example of the data structure of a connection table according to the third embodiment;

FIG. 31 is a diagram that illustrates an example of a method of generating a sorted table;

FIG. 32 is a diagram that illustrates an example of a method of generating a sorted table;

FIG. 33 is a diagram that illustrates an example of a connection table;

FIG. 34 is a schematic diagram that illustrates some vias and some planes that are represented by the sorted table illustrated in the example represented in FIG. 32;

FIG. 35 is a diagram that illustrates an example of the thickness of a segment that is drawn by the drawing unit;

FIG. 36 is a diagram that illustrates an example of the thicknesses of segments that are drawn by the drawing unit;

FIG. 37 is a flowchart that illustrates the sequence of a plane voltage drop drawing process according to the third embodiment;

FIG. 38 is a diagram that illustrates an example of the functional configuration of a drawing device acquired by adding a function of a determination process to the drawing device according to each embodiment;

FIG. 39 is a flowchart that illustrates the sequence of a drawing process to which the determination process is added;

FIGS. 40A and 40B are flowcharts that illustrate the sequence of the determination process; and

FIG. 41 is a diagram that illustrates a computer that executes drawing program.

### DESCRIPTION OF EMBODIMENTS

Preferred embodiments of the present invention will be explained with reference to accompanying drawings.

However, the embodiments are not for the purpose of limiting the technology to be disclosed. In addition, the embodiments can be appropriately combined with each other in a range in which the process contents are not contradictory to each other.

### [a] First Embodiment

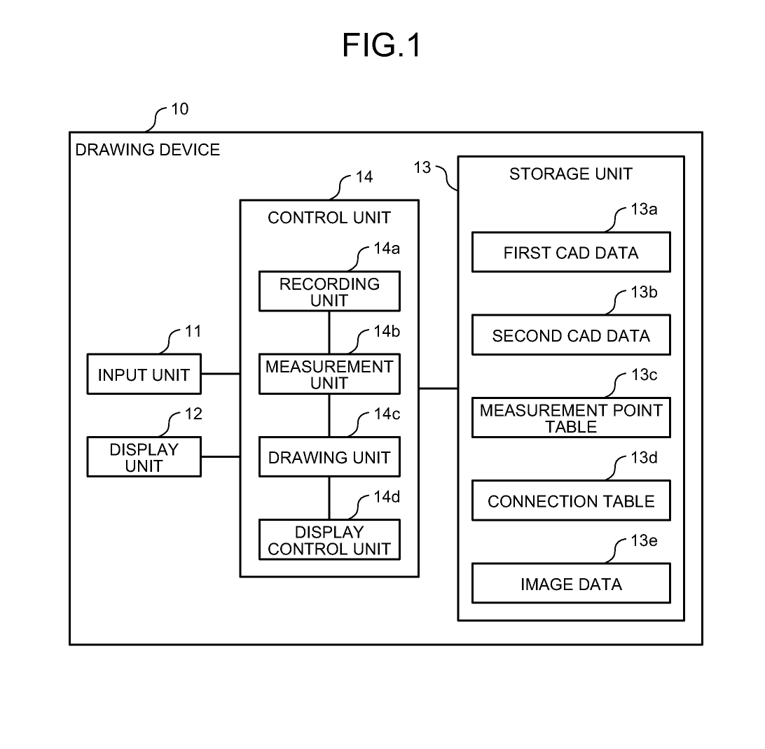

Hereinafter, a drawing device according to a first embodiment will be described. FIG. 1 is a diagram that illustrates an example of the functional configuration of the drawing device according to the first embodiment.

Functional Configuration of Drawing Device 10

As illustrated in FIG. 1, a drawing device 10 includes an input unit 11, a display unit 12, a storage unit 13, and a control unit 14.

The input unit 11 inputs various kinds of information to the control unit 14. For example, the input unit 11 receives an instruction that is used for performing a drawing process to be described below from a user and inputs the received instruction to the control unit 14. In addition, the input unit 11 receives various instructions from the user and inputs the received instruction to the control unit 14. As an example of the device that is used as the input unit 11, there is a device such as a mouse or a keyboard that receives a user's operation.

The display unit 12 displays various kinds of information. For example, the display unit 12 displays a graph, in which voltages of planes of a laminated circuit board is drawn, having the voltage represented in one axis and the layer represented in the other axis under the control of a display control unit 14d to be described below. As an example of a device that is used as the display unit 12, there is a liquid crystal display.

The storage unit 13 stores various kinds of information. For example, the storage unit 13 stores first computer aided design (CAD) data 13a, second CAD data 13b, a measurement point table 13c, a connection table 13d, and image data 13e.

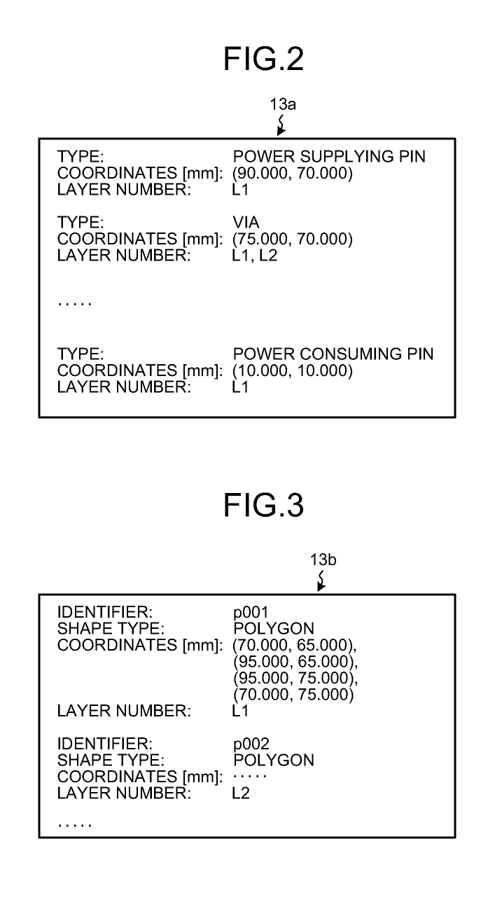

In the first CAD data 13a, information is included in which the types of elements such as a via included in the laminated circuit board, a power supplying pin supplying power, and a power consuming pin consuming power, the positions of the elements, and layers to which the elements are connected are associated with each other. FIG. 2 is a diagram that illustrates an example of the data structure of the first CAD data. In the example represented in FIG. 2, the first CAD data 13a has an entry in which the type of an element included in the laminated circuit board is registered, an entry in which coordinates representing the position of an element are registered, and an entry in which a layer number that is a number of a layer to which an element is connected is registered. The example represented in FIG. 2 illustrates that the coordinates representing the position of an element of which the type is the power supplying pin are (90.000, 70.000), and such an element is connected to a layer of a layer number L1. In addition, the example represented in FIG. 2 illustrates that the coordinates representing an element of which the type is the via are (75.000, 70.000), and such an element is connected to layers of layer numbers L1 and L2. Furthermore, the example represented in FIG. 2 illustrates that the coordinates representing the position of an element of which the type is the power consuming pin are (10.000, 10.000), and such an element is connected to the layer of the layer number L1.

In the second CAD data 13b, information is included in which identifiers of planes included in the laminated circuit board, shapes of the planes that are represented by the identifiers, the coordinates of vertexes of the planes that are represented by the identifiers, and layers in which the planes represented by the identifiers are present are associated with each other. FIG. 3 is a diagram that illustrates an example of the data structure of the second CAD data. In the example represented in FIG. 3, the second CAD data 13b has an entry in which an identifier of a plane included in the laminated circuit board is registered, an entry in which a type of the shape of a plane represented by the identifier is registered, and an entry in which coordinates of vertexes of the plane represented by the identifier are registered. In addition, in the example represented in FIG. 3, the second CAD data 13b has an entry in which a layer number of a layer in which the plane represented by the identifier is present is registered. The example represented in FIG. 3 illustrates a case in which the type of the shape of a plane that is represented by an identifier p001 is a polygon. In addition, the example represented in FIG. 3 illustrates a case in which the coordinates of vertexes of the plane represented by the identifier p001 are (70.000, 65.000), (95.000, 65.000), (95.000, 75.000), and (70.000, 75.000). Furthermore, the example represented in FIG. 3 illustrates a case in which the layer number of a layer in which the plane represented by the identifier p001 is present is L1.

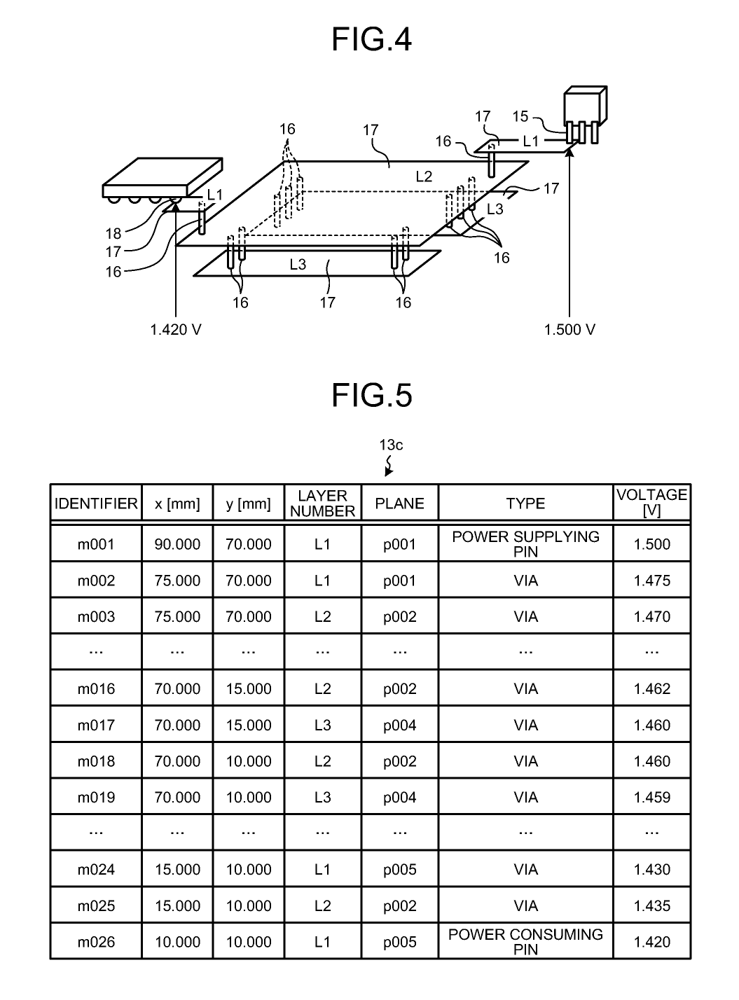

Here, a laminated circuit board that includes vias, a power supplying pin, and a power consuming pin that are represented by the first CAD data 13a and planes that are represented by the second CAD data 13b will be described. FIG. 4 is a schematic diagram of the laminated circuit board. The laminated circuit board represented by the example represented in FIG. 4 includes a power supplying pin 15, planes 17 that are disposed in layers of layer numbers L1, L2, and L3, vias 16 that connects the planes 17 of each layer, and a power consuming pin 18. In the laminated circuit board illustrated in the example represented by FIG. 4, in a case where power is supplied from the power supplying pin 15 to the power consuming pin 18, a voltage drop of 0.08 V from the power supplying pin 15 to the power consuming pin 18 occurs. The reason for the occurrence of the voltage drop is the presence of resistance in the vias 16 and the planes 17. In this embodiment, the drawing device 10 generates image data 13e from which the appearance of a voltage drop in the laminated circuit board can be easily perceived.

The measurement point table 13c includes information that relates to measurement points at which voltages or currents are measured. In the measurement point table 13c, various kinds of contents are registered by a recording unit 14a and a measurement unit 14b to be described below. FIG. 5 is a diagram that illustrates an example of the data structure of the measurement point table. The measurement point table 13c illustrated in the example represented in FIG. 5 has an entry in which an identifier of a measurement point is registered, an entry in which a value of the x coordinate of a measurement point represented by the identifier is registered, an entry in which a value of the y coordinate of the measurement point represented by the identifier is registered, and an entry in which a layer number of a layer to which an element having the measurement point represented by the identifier can be connected. In addition, the measurement point table 13c illustrated in the example represented in FIG. 5 has an entry in which an identifier of a plane that includes the position of the measurement point represented by the identifier on the inside of the area is registered, an entry in which the type of an element having the measurement point represented by the identifier is registered, and an entry in which a voltage value of the measurement point represented by the identifier is registered.

A first record of the measurement point table 13c represented in FIG. 5 is a record that represents information relating to a measurement point, at which a voltage or a current is measured, of identifier m001. The first record of the measurement point table 13c represented in FIG. 5 represents that the coordinates representing the position of the measurement point of identifier m001 are (90.000, 70.000), and a layer to which an element having the measurement point of identifier m001 can be connected is a layer of layer number L1. In addition, the first record of the measurement point table 13c represented in FIG. 5 represents that a plane of identifier p001 includes the position of the measurement point of identifier m001 inside the area. Furthermore, the first record of the measurement point table 13c represented in FIG. 5 represents that the type of the element having the measurement point of identifier m001 is a power supplying pin, and a voltage value at the measurement point of identifier m001 is 1.5. The other records similarly represent contents thereof.

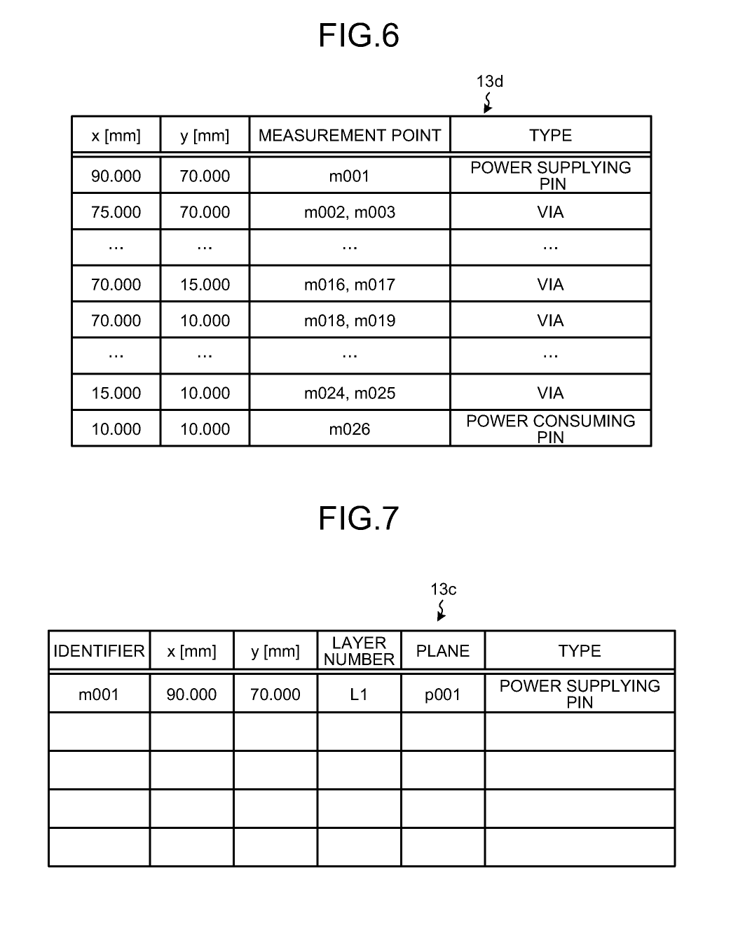

The connection table 13d includes various kinds of information such as a position of a measurement point that is a point at which a voltage or a current is measured, an identifier of the measurement point, and a type of an element having the measurement point. Various kinds of contents are registered in the connection table 13d by a recording unit 14a to be described below. FIG. 6 is a diagram that illustrates an example of the data structure of the connection table. The connection table 13d illustrated in the example represented in FIG. 6 includes: an entry in which a value of the x coordinate of a measurement point represented by an identifier is registered; an entry in which a value of the y coordinate of the measurement point represented by the identifier is registered; and an entry in which a type of an element having the measurement point represented by the identifier is registered. In addition, the connection table 13d illustrated in the example represented in FIG. 6 includes an entry in which the type of an element including a measurement point that is represented by the identifier is registered.

A first record of the connection table 13d represented in FIG. 6 is a record that represents information relating to a measurement point, at which a voltage or a current is measured, of identifier m001. The first record of the connection table 13d represented in FIG. 6 represents that the coordinates representing the position of the measurement point of identifier m001 are (90.000, 70.000), and the type of an element having a measurement point of identifier m001 is the power supplying pin. The other records similarly represent contents thereof.

The image data 13e is generated by a drawing unit 14c to be described below. In the image data 13e, data of a graph in which voltages of planes of the laminated circuit board are drawn, having the voltage as one axis and the layer as the other axis is included. An image that is represented by the image data 13e will be described below.

The storage unit 13, for example, is a semiconductor memory device such as a flash memory or a storage device such as a hard disk or an optical disc. The storage unit 13 is not limited to the storage device of a type described above and may be a random access memory (RAM) or a read only memory (ROM).

The control unit 14 includes an internal memory used for storing a program that defines various processing sequences or control data and performs various processes based on these. As illustrated in FIG. 1, the control unit 14 includes a recording unit 14a, a measurement unit 14b, a drawing unit 14c, and a display control unit 14d.

The recording unit 14a records various kinds of information. For example, the recording unit 14a records various kinds of information in the measurement point table 13c and the connection table 13d. A method of recording information in the measurement point table 13c and the connection table 13d using the recording unit 14a will now be described with reference to a specific example.

The recording unit 14a, first, acquires the first CAD data 13a and the second CAD data 13b from the storage unit 13. Then, the recording unit 14a determines whether or not there is an element, which has not been selected, out of a plurality of elements represented by the first CAD data 13a. Subsequently, in a case where there is an element that has not been selected, the recording unit 14a selects one element, which has not been selected, out of a plurality of elements represented by the first CAD data 13a. Thereafter, the recording unit 14a stores the type of the selected element in parameter t. thereby updating the registered content of parameter t. In addition, the recording unit 14a stores the coordinates of a position at which the selected element is located in parameter (x, y), thereby updating the registered content of parameter (x, y). Thereafter, the recording unit 14a sorts the layers of planes to which the selected element can be connected in the ascending order.

For example, the recording unit 14a acquires the first CAD data illustrated in FIG. 2. Then, in a case where the via illustrated in the example represented in FIG. 2 is selected as an element that has not been selected, the recording unit 14a stores “via” in parameter t and stores (75.000, 70.000) in parameter (x, y). Then, the recording unit 14a sorts layers of planes to which the selected via can be connected, in other words, layers of layer numbers L1 and L2 in the ascending order.

Then, the recording unit 14a determines whether or not there is a layer z that has not been selected out of the layers that are sorted in the ascending order. In a case where there is no layer z that has not been selected, the recording unit 14a performs the above-described process of determining whether or not there is an element that has not been selected out of a plurality of elements represented by the first CAD data 13a again and, as described above, performs the subsequent processes after the process of determining whether or not there is an element that has not been selected again.

On the other hand, in a case where there is a layer z that has not been selected, the recording unit 14a selects one layer that is a layer z that has not been selected and is a layer z that has a least layer number out of the sorted layers. Then, the recording unit 14a determines whether or not there is a plane p that has not been selected out of planes that are present in the selected layer z by referring to the second CAD data 13b. In a case where there is no plane p that has not been selected, the recording unit 14a performs the above-described process of determining whether or not there is a layer z that has not been selected again and, as described above, performs the subsequent processes after the process of determining whether or not there is a layer z that has not been selected again.

On the other hand, in a case where there is a plane p that has not been selected, the recording unit 14a selects one plane p that has not been selected out of planes that are present in the selected layer z. Then, the recording unit 14a determines whether or not the coordinates stored in parameter (x, y) are present inside the area of the selected plane p by referring to the second CAD data. In a case where the coordinates are not present on the inside, the recording unit 14a performs the above-described process of determining whether or not there is a plane p that has not been selected out of planes that are present in the selected layer z again and, as described above, performs the subsequent processes after the process of determining whether or not there is a plane p that has not been selected again.

On the other hand, in a case where the coordinates stored in parameter (x, y) are present inside the area of the selected plane p, the recording unit 14a performs a process as follows. That is, the recording unit 14a stores the value of the x coordinate and the value of the y coordinate of coordinates stored in parameter (x, y), a layer number of the selected layer z, an identifier of the selected plane p, and the type of the element stored in parameter t in association with the identifier m of the measurement point in the measurement point table 13c.

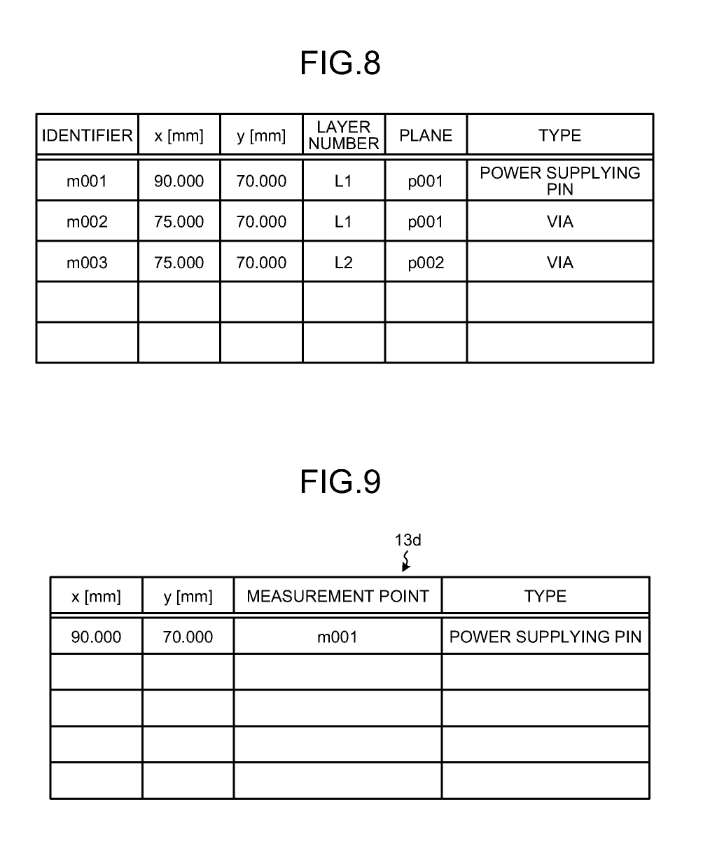

A specific example of recording various kinds of information in the measurement point table 13c will be described. FIGS. 7 and 8 are diagrams that illustrate examples of the process of recording various kinds of information in the measurement point table. For example, a case will be described in which coordinates stored in parameter (x, y) are (90.000, 70.000), the layer number of a selected layer z is L1, the identifier of a selected plane p is p001, and the type of an element that is stored in parameter t is the power supplying pin. In such a case, when the identifier of a measurement point is m001, the recording unit 14a, as illustrated in the example represented in FIG. 7, records m001 in the entry in which an identifier of a measurement point is registered and records 90.000 in the entry in which the value of the x coordinate of the measurement point represented by the identifier is registered. In addition, the recording unit 14a, as illustrated in the example represented in FIG. 7, records 70.000 in the entry in which a y coordinate of the measurement point represented by the identifier is registered and records L1 in the entry in which a layer number of a layer to which an element having the measurement point represented by the identifier can be connected is registered. Furthermore, the recording unit 14a, as illustrated in the example represented in FIG. 7, records p001 in the entry in which an identifier of a plane that includes the position of the measurement point represented by the identifier on the inside of the area is registered and records the power supplying pin in the entry in which the type of an element having the measurement point represented by the identifier is registered.

In addition, a case will be described in which coordinates stored in parameter (x, y) are (75.000, 70.000), the layer number of a selected layer z is L1, the identifier of a selected plane p is p001, and the type of an element that is stored in parameter t is the via. In such a case, when the identifier of a measurement point is m002, the recording unit 14a, as illustrated in the example represented in FIG. 8, records m002 in the entry in which an identifier of a measurement point is registered and records 75.000 in the entry in which the value of the x coordinate of the measurement point represented by the identifier is registered. In addition, the recording unit 14a, as illustrated in the example represented in FIG. 8, records 70.000 in the entry in which a y coordinate of the measurement point represented by the identifier is registered and records L1 in the entry in which a layer number of a layer to which an element having the measurement point represented by the identifier can be connected is registered. Furthermore, the recording unit 14a, as illustrated in the example represented in FIG. 8, records p001 in the entry in which an identifier of a plane that includes the position of a measurement point represented by the identifier on the inside of the area is registered and records the via in the entry in which the type of an element having the measurement point represented by the identifier is registered.

Furthermore, a case will be described in which coordinates stored in parameter (x, y) are (75.000, 70.000), the layer number of a selected layer z is L2, the identifier of a selected plane p is p002, and the type of an element that is stored in parameter t is the via. In such a case, when the identifier of a measurement point is m003, the recording unit 14a, as illustrated in the example represented in FIG. 8, records m003 in the entry in which an identifier of a measurement point is registered and records 75.000 in the entry in which the value of the x coordinate of the measurement point represented by the identifier is registered. In addition, the recording unit 14a, as illustrated in the example represented in FIG. 8, records 70.000 in the entry in which a y coordinate of the measurement point represented by the identifier is registered and records L2 in the entry in which a layer number of a layer to which an element having the measurement point represented by the identifier can be connected is registered. Furthermore, the recording unit 14a, as illustrated in the example represented in FIG. 8, records p002 in the entry in which an identifier of a plane that includes the position of a measurement point represented by the identifier on the inside of the area is registered and records the via in the entry in which the type of an element having the measurement point represented by the identifier is registered.

Then, the recording unit 14a determines whether or not the type of the element that is stored in parameter t is the via. In a case where the type is not the via, the recording unit 14a records a value of the x coordinate and a value of the y coordinate of coordinates stored in parameter (x, y) and the type of an element that is stored in parameter t in association with the identifier m of the measurement point in the connection table 13d. Then, the recording unit 14a performs the above-described process of determining whether or not there is a plane p that has not been selected out of planes present in the selected layer z again and, as described above, performs subsequent processes after the process of determining whether or not there is a plane p that has not been selected again.

On the other hand, in a case where the type of the element that is stored in parameter t is the via, the recording unit 14a determines whether or not the selected layer z is an uppermost layer of sorted layers. In a case where the selected layer is the uppermost layer, the recording unit 14a stores an identifier m of the measurement point in parameter m′, thereby updating the registered content of parameter m′. Then, the recording unit 14a performs the above-described process of determining whether or not there is a plane p that has not been selected out of the planes present in the selected layer z again and, as described above, performs the subsequent processes after the process of determining whether or not there is a plane p that has not been selected again.

Here, in a case where the selected layer z is not the uppermost layer of the sorted layers, the recording unit 14a performs a process as follows. That is, the recording unit 14a records a value of the x coordinate and a value of the y coordinate of coordinates stored in parameter (x, y) and the type of an element that is stored in parameter t in association with the identifier m of the measurement point and the identifier of a measurement point that is stored in parameter m′ in the connection table 13d. Then, the recording unit 14a stores the identifier m of the measurement point in parameter m′, thereby updating the registered content of parameter m′. Thereafter, the recording unit 14a performs the above-described process of determining whether or not there is a plane p that has not been selected out of the planes present in the selected layer z again and, as described above, performs the subsequent processes after the process of determining whether or not there is a plane p that has not been selected again.

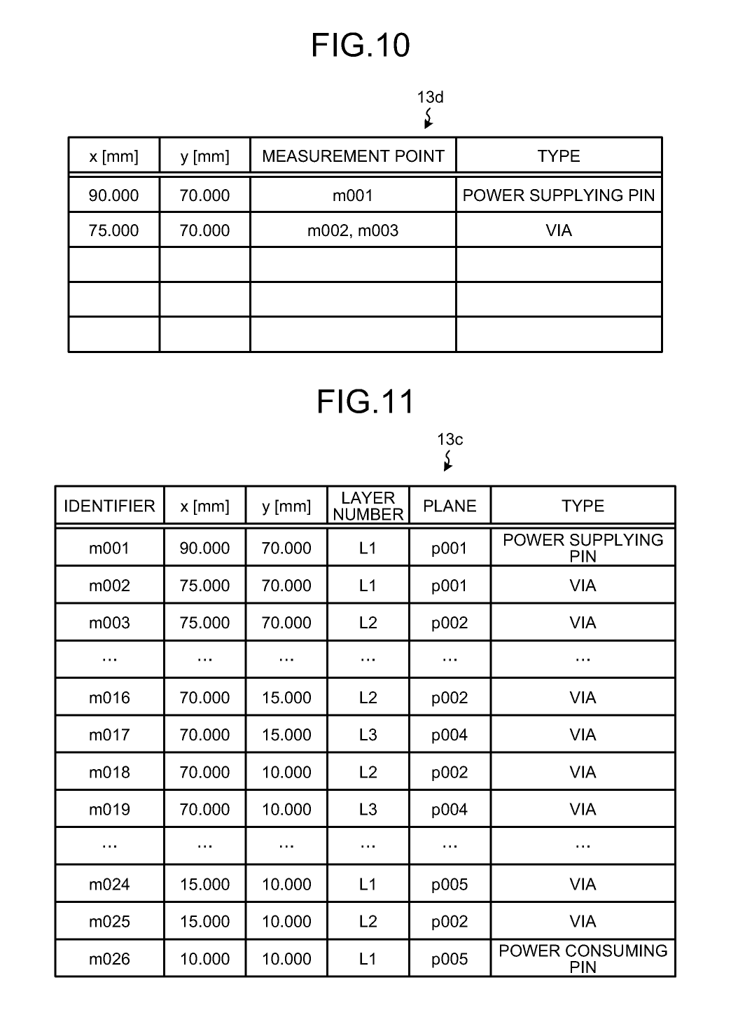

A specific example of recording various kinds of information in the connection table 13d will be described. FIGS. 9 and 10 are diagrams that illustrate examples of the process of recording various kinds of information in the connection table. For example, a case will be described in which coordinates stored in parameter (x, y) are (90.000, 70.000), and the type of an element that is stored in parameter t is the power supplying pin. In such a case, when the identifier of a measurement point is m001, the recording unit 14a, as illustrated in the example represented in FIG. 9, records 90.000 in the entry in which the value of the x coordinate of the measurement point represented by the identifier is registered and records 70.000 in the entry in which the value of the y coordinate of the measurement point represented by the identifier is registered. In addition, the recording unit 14a, as illustrated in the example represented in FIG. 9, records m001 in the entry in which an identifier of the measurement point is registered and records the power supplying pin in the entry in which the type of an element having the measurement point represented by the identifier is registered.

In addition, a case will be described in which coordinates stored in parameter (x, y) are (75.000, 70.000), the type of an element that is stored in parameter t is the via, and the identifier of a measurement point that is stored in parameter m′ is m002. In such a case, when the identifier of the measurement point is m003, the recording unit 14a, as illustrated in the example represented in FIG. 10, records 75.000 in the entry in which the value of the x coordinate of a measurement point that is represented by the identifier is registered and records 70.000 in the entry in which the value of the y coordinate of the measurement point that is represented by the identifier is registered. In addition, the recording unit 14a, as illustrated in the example represented in FIG. 10, records m002 and m003 in the entry in which an identifier of a measurement point is registered and registers the via in the entry in which the type of an element having the measurement point represented by the identifier is registered. Here, the measurement point represented by the identifier that is stored in parameter m′ and the measurement point represented by an identifier m that is newly assigned are measurement points included in the same via. In such a case, the measurement point represented by the identifier stored in parameter m′ is disposed in a layer that is located upper than a layer in which the measurement point represented by the identifier m that is newly assigned is disposed.

The recording unit 14a repeatedly performs the above-described process until there is no element that has not been selected. FIG. 11 is a diagram that illustrates an example of the measurement point table in which various kinds of information is recorded by the recording unit. By performing the above-described process until there is no element that has not been selected, repeatedly, the recording unit 14a generates the measurement point table 13c as illustrated in the example represented in FIG. 11 and the connection table 13d as illustrated in the previous example represented in FIG. 6.

The measurement unit 14b measures a voltage of a plane of each layer and voltages of via in the laminated circuit board. A specific example will be described. First, the measurement unit 14b acquires the measurement point table 13c from the storage unit 13 and measures voltages v of all the measurement points that are registered in the measurement point table 13c. As an example of a method of measuring the voltages, there is a simulation such as a PEEC method. However, the method of measuring the voltages is not limited thereto, but an arbitrary method can be used.

Then, the measurement unit 14b selects one measurement point, which has not been selected, out of all the measurement points registered in the measurement point table 13c. Thereafter, the measurement unit 14b registers information, which is registered in the measurement point table 13c, corresponding to the selected measurement point in association with a voltage v at the selected measurement point in the measurement point table 13c, thereby updating the measurement point table 13c. The measurement unit 14b repeatedly performs the process of updating the measurement point table 13c by registering the information in the measurement point table 13c in association with the voltage v at the selected measurement point until there is no measurement point that has not been selected. In this way, for example, as illustrated in the previous example represented in FIG. 5, voltage values at the measurement points are recorded in the measurement point table 13c.

The drawing unit 14c draws the voltages of the planes that are measured by the measurement unit 14b on a graph having the voltage as one axis and having the layer as the other axis. A specific example will be described. First, the drawing unit 14c acquires the measurement point table 13c and specifies a minimal voltage v1 from the measurement point table 13c. In addition, the drawing unit 14c specifies a maximal voltage v2 from the measurement point table 13c. Furthermore, the drawing unit 14c specifies a minimal layer number z1 from the measurement point table 13c. In addition, the drawing unit 14c specifies a maximal layer number z2 from the measurement point table 13c. For example, in a case where the measurement point table 13c illustrated in the example represented in FIG. 5 is acquired, the drawing unit 14c specifies a minimal voltage 1.420 [V], a maximal voltage 1.500 [V], a minimal layer number L1, and a maximal layer number L3.

Then, the drawing unit 14c generates a drawing area, which can include a rectangular area {(v1, z1), (v2, z1), (v2, z2), (v1, z1)} and constituent elements such as axes, for a graph. Then, the drawing unit 14c draws the X axis that includes section [v1, v2] in the drawing area. In addition, the drawing unit 14c draws the Y axis that includes section [z1, z2] in the drawing area.

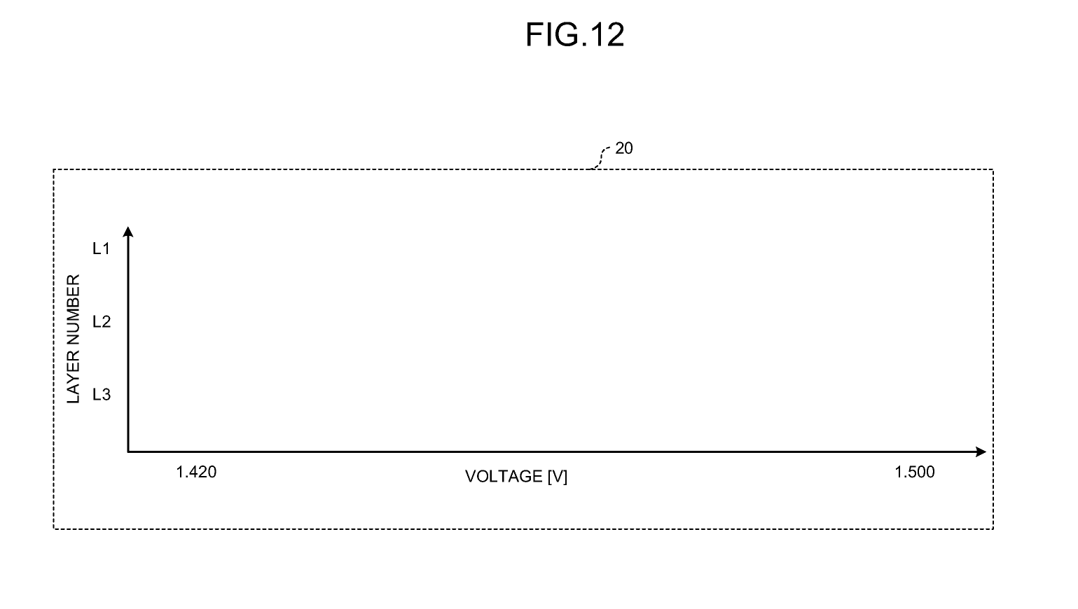

FIG. 12 is a diagram that illustrates an example of the X axis and the Y axis that are drawn by the drawing unit. In the example represented in FIG. 12, a drawing area 20 that is generated by the drawing unit 14c is illustrated. Such a drawing area 20 is an area that can include a rectangular area {(v1, z1), (v2, z1), (v2, z2), (v1, z1)} and constituent elements such as axes. In the example represented in FIG. 12, a case is illustrated as an example in which the X axis including section [1.420, 1.500] is drawn in the drawing area 20 by the drawing unit 14c. In addition, in the example represented in FIG. 12, a case is illustrated as an example in which the Y axis including section [L1, L3] is drawn in the drawing area 20 by the drawing unit 14c. Furthermore, in the example represented in FIG. 12, a case is illustrated as an example in which the drawing unit 14c draws a “voltage [V]” in correspondence with the X axis and draws a “layer number” in correspondence with the Y axis.

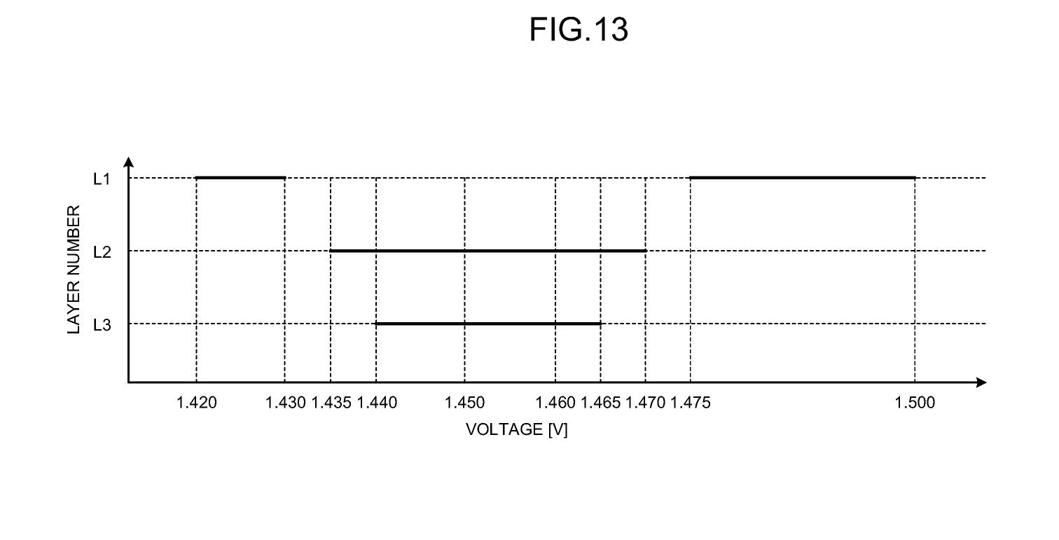

Subsequently, the drawing unit 14c determines whether or not there is a plane p that has not been selected out of planes of which identification numbers are registered in the measurement point table 13c. In a case where there is a plane p that has not been selected, the drawing unit 14c selects one plane p that has not been selected. Then, the drawing unit 14c specifies a minimal voltage v3 and a maximal voltage v4 of the selected plane p and a layer z of the selected plane p from the measurement point table 13c. Thereafter, the drawing unit 14c draws a segment (v3, z)-(v4, z) in the drawing area of the graph. The drawing unit 14c repeatedly performs such a process until there is no plane p that has not been selected. FIG. 13 is a diagram that illustrates an example of a segment formed by a minimal voltage and a maximal voltage of each plane that is drawn by the drawing unit. In the example represented in FIG. 13, a case is illustrated as an example in which a segment (1.475, L1)-(1.500, L1) is drawn in the drawing area of the graph by the drawing unit 14c. In addition, in the example represented in FIG. 13, a case is illustrated as an example in which a segment (1.440, L3)-(1.460, L3) is drawn in the drawing area of the graph by the drawing unit 14c. Furthermore, in the example represented in FIG. 13, a case is illustrated as an example in which a segment (1.450, L3)-(1.465, L3) is drawn in the drawing area of the graph by the drawing unit 14c. In addition, in the example represented in FIG. 13, a case is illustrated as an example in which a segment (1.435, L2)-(1.470, L2) is drawn in the drawing area of the graph by the drawing unit 14c. Furthermore, in the example represented in FIG. 13, a case is illustrated as an example in which a segment (1.420, L1)-(1.430, L1) is drawn in the drawing area of the graph by the drawing unit 14c.

In this way, the drawing device 10 according to this embodiment draws voltages of planes on the graph in which the voltage is set on the X axis, and the layer is set on the Y axis. Therefore, according to the drawing device 10, an image can be presented from which the appearance of a voltage drop of each plane in the laminated circuit board can be perceived in an easy manner.

Subsequently, the drawing unit 14c determines whether or not there is a record that has not been selected out of records in which the “via” is registered in the entry in which the type of an element is registered in the connection table 13d. In a case where there is a record that has not been selected, the drawing unit 14c selects one record that has not been selected. Then, the drawing unit 14c specifies a set (m′, m) of identifiers of measurement points that are included in the selected record. Thereafter, the drawing unit 14c specifies a voltage v(m′) at the measurement point that is represented by the identifier stored in parameter m′ from the measurement point table 13c. In addition, the drawing unit 14c specifies a voltage v(m) at the measurement point that is represented by the identifier m from the measurement point table 13c. Furthermore, the drawing unit 14c specifies a layer number z(m′) of a layer in which a measurement point represented by the identifier stored in parameter m′ is present from the measurement point table 13c. In addition, the drawing unit 14c specifies a layer number z(m) of a layer in which the measurement point represented by the identifier m is present from the measurement point table 13c. Thereafter, the drawing unit 14c draws a segment (v(m′), z(m′))-(v(m), z(m)) in the drawing area of the graph. Here, the segment (v(m′), z(m′))-(v(m), z(m)) is a segment that represents a voltage drop of a via that has measurement points corresponding to the identifiers m′ and m. The drawing unit 14c repeatedly performs such a process until there is no record that has not been selected out of records in which the “via” is registered in the entry in which the type of an element is registered in the connection table 13d. Then, in a case where there is no record that has not been selected, the drawing unit 14c stores image data 13e of the graph for which various kinds of drawing processes have been performed in the storage unit 13.

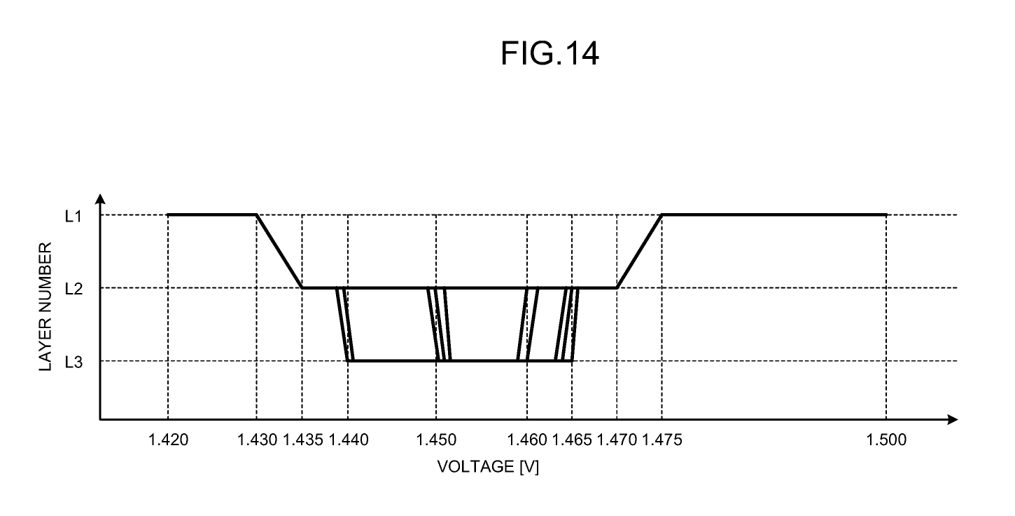

FIG. 14 is a diagram that illustrates an example of a segment representing a voltage drop of a via that is drawn by the drawing unit. A graph that is illustrated in the example represented in FIG. 14 represents a case where the drawing unit 14c draws a segment representing a voltage difference between two measurement point included in each via in addition to the drawn content of the graph illustrated in the example represented in FIG. 13.

In this way, the drawing device 10 according to this embodiment draws a voltage of each via on the graph in which the voltage is set on the X axis, and the layer is set on the Y axis. Therefore, according to the drawing device 10, an image can be presented from which the appearance of a voltage drop of each via in the laminated circuit board can be perceived in an easy manner.

The display control unit 14d acquires the image data 13e that is generated by the drawing unit 14c and is stored in the storage unit 13 and performs controls of a display that is made by the display unit 12 such that an image represented by the image data 13e is displayed. Here, for example, this image is a graph as illustrated in the previous example represented in FIG. 14.

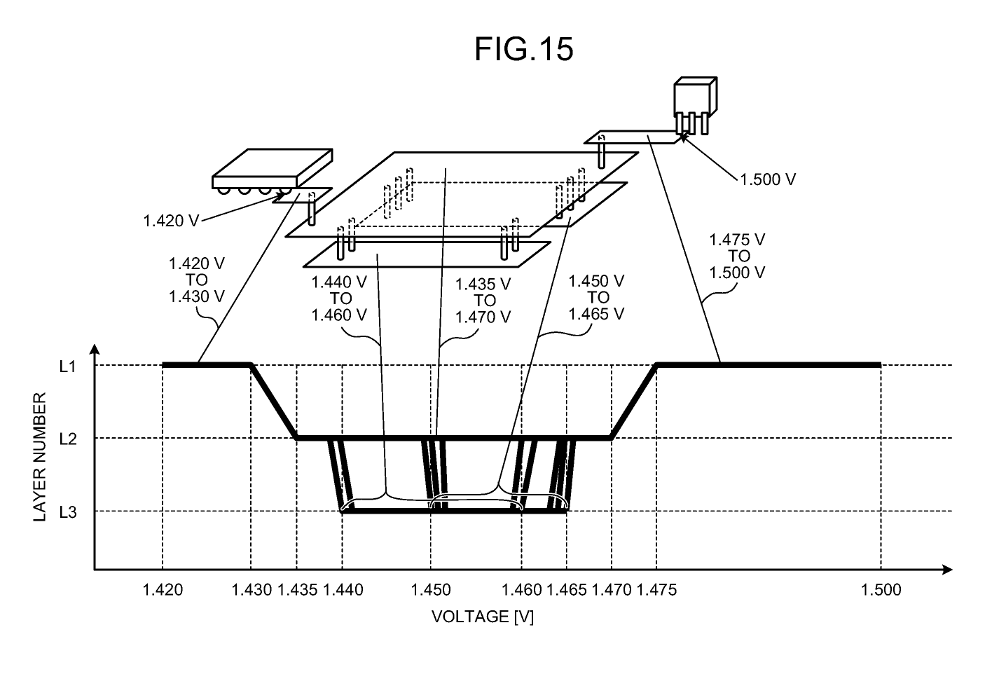

FIG. 15 is a diagram that illustrates the correspondence relation between the generated graph and a plane, a via, a power supplying pin, and a power consuming pin of the laminated circuit board. As illustrated in the example represented in FIG. 15, the drawing device 10 according to this embodiment can generate a graph from which the appearance of voltage drops of the via, and the like can be perceived in an easy manner. In this way, according to the drawing device 10 of this embodiment, an image from which an analysis of the laminated circuit board can be easily performed can be generated.

As described above, the drawing device 10 according to this embodiment draws the appearance of a voltage drop of each plane on a graph in which the voltage is set on the X axis and the layer is set on the Y axis. Then, the drawing device 10 performs control such that the drawn graph is displayed. Therefore, according to the drawing device 10, control can be performed such that an image from which the appearance of a voltage drop of each plane in the laminated circuit board can be easily perceived is displayed.

In addition, the drawing device 10 according to this embodiment draws the appearance of a voltage drop of each via on a graph in which the voltage is set on the X axis and the layer is set on the Y axis. Therefore, according to the drawing device 10, control can be performed such that an image from which the appearance of a voltage drop of each via in the laminated circuit board can be easily perceived is displayed.

The control unit 14 is an integrated circuit such as an application specific integrated circuit (ASIC) or a field programmable gate array (FPGA) or an electronic circuit such as a central processing unit (CPU) or a micro processing unit (MPU).

Flow of Process

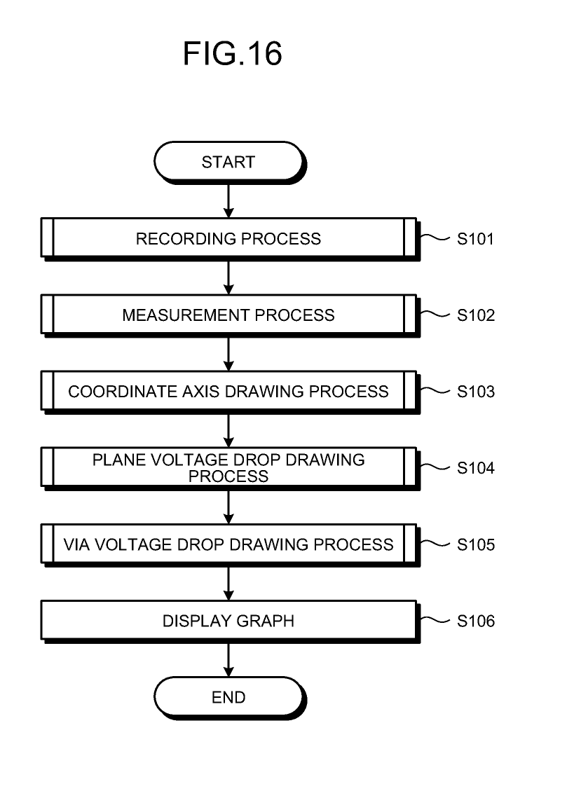

Next, the flow of the process of the drawing device 10 according to this embodiment will be described. FIG. 16 is a flowchart that illustrates the sequence of a drawing process according to the first embodiment. The drawing process, for example, is performed at timing when an instruction for performing the drawing process is received from the input unit 11 by the control unit 14.

As illustrated in FIG. 16, the recording unit 14a performs a recording process in Step S101. Then, the measurement unit 14b performs a measurement process in Step S102. Subsequently, the drawing unit 14c performs a coordinate axis drawing process in Step S103. Thereafter, the drawing unit 14c performs a plane voltage drop drawing process in Step S104. Then, the drawing unit 14c performs a via voltage drop drawing process in Step S105. Thereafter, the display control unit 14d performs control of a display made by the display unit 12 so as to display a graph represented by image data 13e in Step S106, and the process ends.

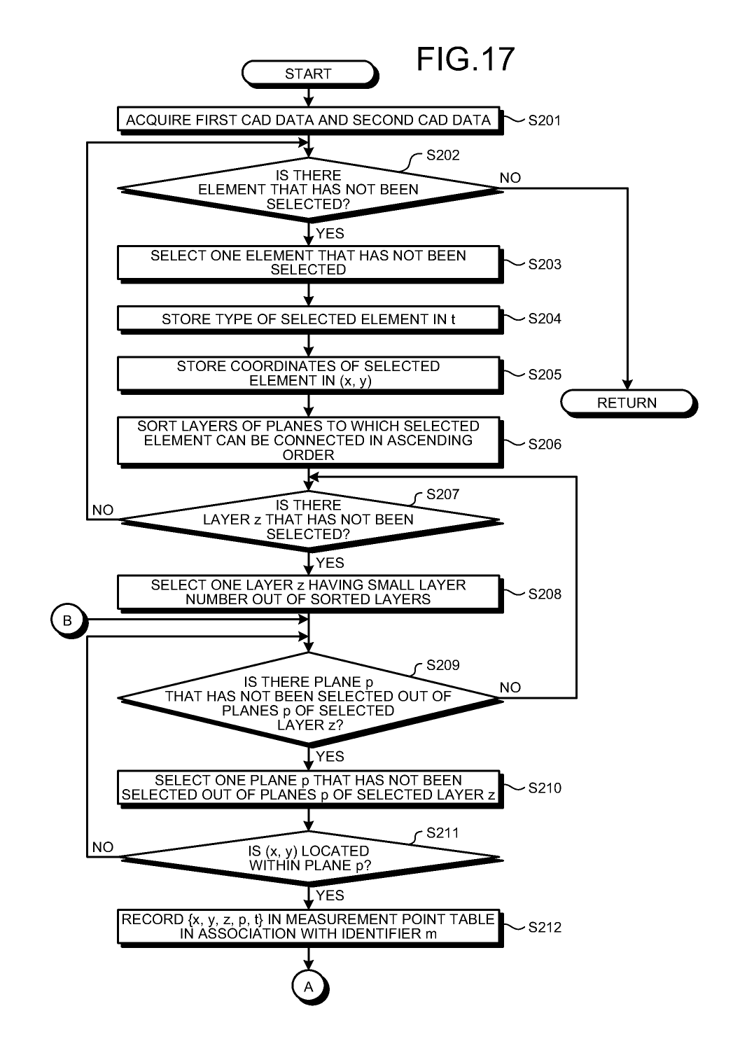

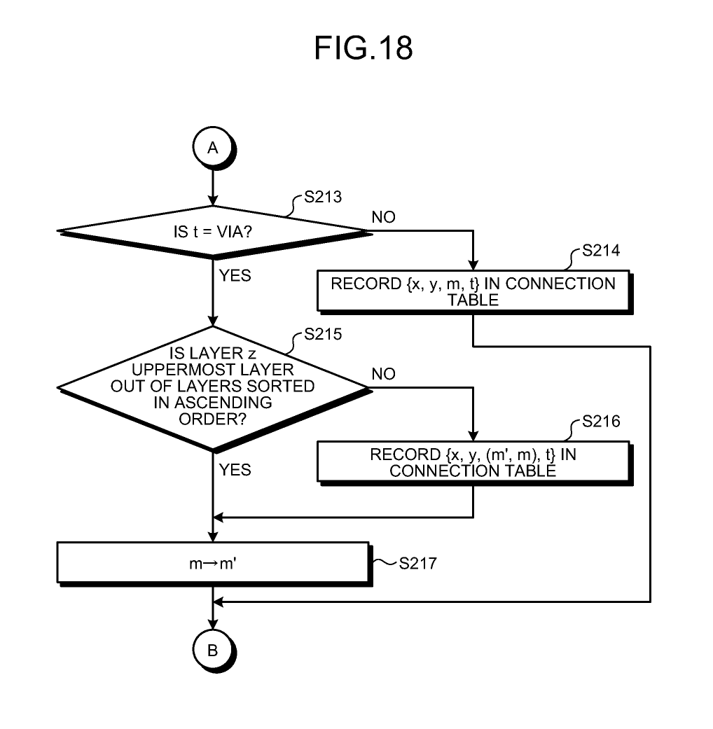

FIGS. 17 and 18 are flowcharts that illustrate the sequence of a recording process according to the first embodiment. As illustrated in FIG. 17, the recording unit 14a acquires the first CAD data 13a and the second CAD data 13b from the storage unit 13 in Step S201. Then, the recording unit 14a determines whether or not there is an element that has not been selected out of a plurality of elements that are represented by the first CAD data 13a in Step S202. In a case where there is no element that has not been selected (No in Step S202), the recording unit 14a stores the processing result in an internal memory, and the process is returned. On the other hand, in a case where there is an element that has not been selected (Yes in Step S202), the recording unit 14a selects one element that has not been selected out of the plurality of elements that are represented by the first CAD data 13a in Step S203. Thereafter, the recording unit 14a stores the type of the selected element in parameter t, thereby updating the registered content of parameter t in Step S204. Then, the recording unit 14a stores coordinates at which the selected element is located in parameter (x, y), thereby updating the registered content of parameter (x, y) in Step S205. Thereafter, the recording unit 14a sorts layers of planes to which the selected element can be connected in the ascending order in Step S206.

Then, the recording unit 14a determines whether or not there is a layer z that has not been selected out of the layers sorted in the ascending order in Step S207. In a case where there is no layer z that has not been selected (No in Step S207), the process is returned to Step S202. On the other hand, in a case where there is a layer z that has not been selected (Yes in Step S207), the recording unit 14a selects one layer that is a layer z having not been selected out of the sorted layers and is a layer z having a least layer number in Step S208. Then, the recording unit 14a determines whether or not there is a plane p that has not been selected out of planes that are present in the selected layer z by referring to the second CAD data 13b in Step S209. In a case where there is no plane p that has not been selected (No in Step S209), the process is returned to Step S207.

On the other hand, in a case where there is a plane p that has not been selected (Yes in Step S209), the recording unit 14a selects one plane p that has not been selected out of planes that are present in the selected layer z in Step S210. Then, the recording unit 14a determines whether or not the coordinates stored in parameter (x, y) are present inside the area of the selected plane p by referring to the second CAD data in Step S211. In a case where the coordinates are not present therein (No in Step S211), the process is returned to Step S209.

On the other hand, in a case where the coordinates are present therein (Yes in Step S211), the recording unit 14a performs a process as follows. That is, the recording unit 14a records the value of the x coordinate and the value of the y coordinate of the coordinates stored in parameter (x, y), the layer number of the selected layer z, the identifier of the selected plane p, and the type of the element that is stored in parameter t in the measurement point table 13c in association with the identifier m of the measurement point in Step S212.

Then, the recording unit 14a determines whether or not the type of the element that is stored in parameter t is the via in Step S213. In a case where the type is not the via (No in Step S213), the recording unit 14a records the value of the x coordinate and the value of the y coordinate of the coordinates stored in parameter (x, y) and the type of an element that is stored in parameter t in association with the identifier m of the measurement point in the connection table 13d in Step S214, and the process is returned to Step S209.

On the other hand, in a case where the type is the via (Yes in Step S213), the recording unit 14a determines whether or not the selected layer z is an uppermost layer of the sorted layers in Step S215. In the case of the uppermost layer (Yes in Step S215), the recording unit 14a stores the identifier m of the measurement point in parameter m′, updates the registered content of parameter m′ in Step S217, and the process is returned to Step S209.

On the other hand, in a case where the selected layer is not an uppermost layer (No in Step S215), the recording unit 14a performs a process as follows. That is, the recording unit 14a records the value of the x coordinate and the value of the y coordinate of the coordinates stored in parameter (x, y) and the type of the element that is stored in parameter t in the connection table 13d in association with the identifier m of the measurement point and the identifier of the measurement point that is stored in parameter m′ in Step S216. Then, the process proceeds to Step S217.

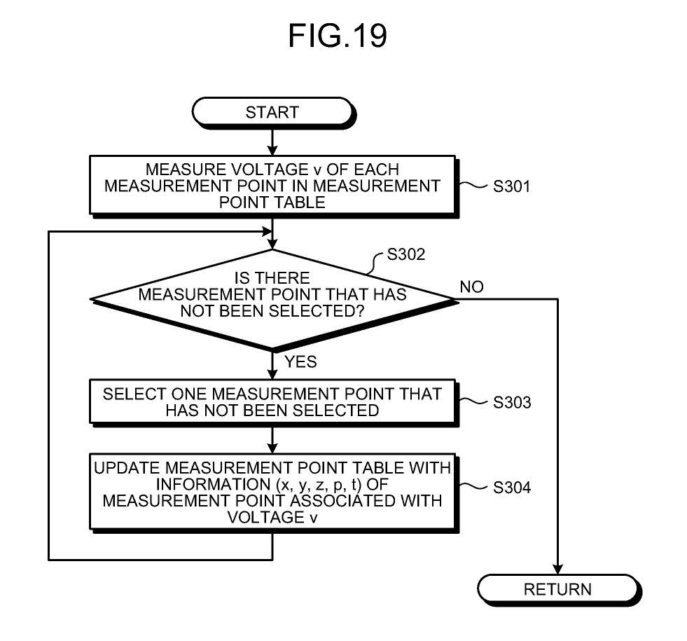

FIG. 19 is a flowchart that illustrates the sequence of a measurement process according to the first embodiment. As illustrated in FIG. 19, the measurement unit 14b acquires the measurement point table 13c from the storage unit 13 and measures voltages v of all the measurement points registered in the measurement point table 13c in Step S301.

Then, the measurement unit 14b determines whether or not there is a measurement point that has not been selected out of all the measurement points registered in the measurement point table 13c in Step S302. In a case where there is no measurement point that has not been selected (No in Step S302), the measurement unit 14b stores the processing result in an internal memory, and the process is returned. On the other hand, in a case where there is a measurement point that has not been selected (Yes in Step S302), the measurement unit 14b selects one measurement point that has not been selected out of all the measurement points registered in the measurement point table 13c in Step S303. Thereafter, the measurement unit 14b registers information that is registered in the measurement point table 13c that corresponds to the selected measurement point in the measurement point table 13c in association with the voltage v at the selected measurement point so as to update the measurement point table 13c in Step S304, and the process proceeds to Step S302.

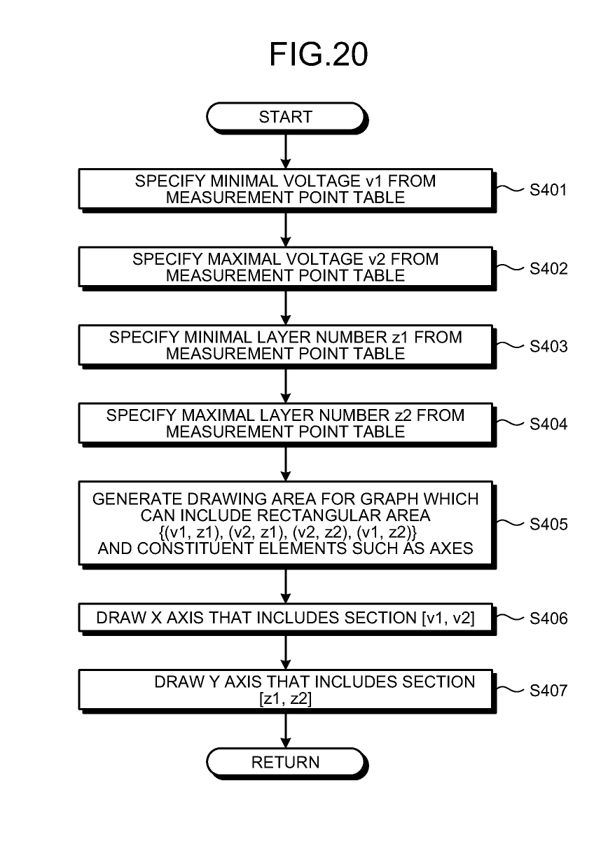

FIG. 20 is a flowchart that illustrates the sequence of a coordinate-axis drawing process according to the first embodiment. As illustrated in FIG. 20, the drawing unit 14c acquires the measurement point table 13c and specifies a minimal voltage v1 from the measurement point table 13c in Step S401. Then, the drawing unit 14c specifies a maximal voltage v2 from the measurement point table 13c in Step S402. Subsequently, the drawing unit 14c specifies a minimal layer number z1 from the measurement point table 13c in Step S403. Thereafter, the drawing unit 14c specifies a maximal layer number z2 from the measurement point table 13c in Step S404.

Then, the drawing unit 14c generates a drawing area, which can include a rectangular area {(v1, z1), (v2, z1), (v2, z2), (v1, z1)} and constituent elements such as axes, for a graph in Step S405. Subsequently, the drawing unit 14c draws the X axis that includes section [v1, v2] in the drawing area in Step S406. Thereafter, the drawing unit 14c draws the Y axis that includes section [z1, z2] in the drawing area in Step S407 and stores the processing result in the internal memory, and the process is returned.

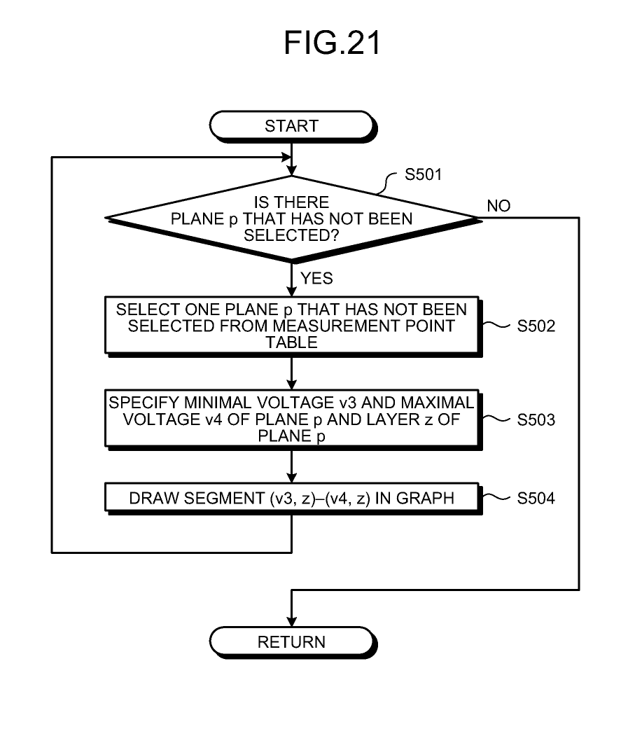

FIG. 21 is a flowchart that illustrates the sequence of a plane voltage drop drawing process according to the first embodiment. As illustrated in FIG. 21, the drawing unit 14c determines whether or not there is a plane p that has not been selected out of planes of which the identification numbers are registered in the measurement point table 13c in Step S501. In a case where there is no plane p that has not been selected (No in Step S501), the drawing unit 14c stores the processing result in the internal memory, and the process is returned. On the other hand, in a case where there is a plane p that has not been selected (Yes in Step S501), the drawing unit 14c selects one plane p that has not been selected in Step S502. Then, the drawing unit 14c specifies a minimal voltage v3 and a maximal voltage v4 of the selected plane p and the layer z of the selected plane p from the measurement point table 13c in Step S503. Thereafter, the drawing unit 14c draws a segment (v3, z)-(v4, z) in the drawing area of the graph in Step S504, and the process is returned to Step S501.

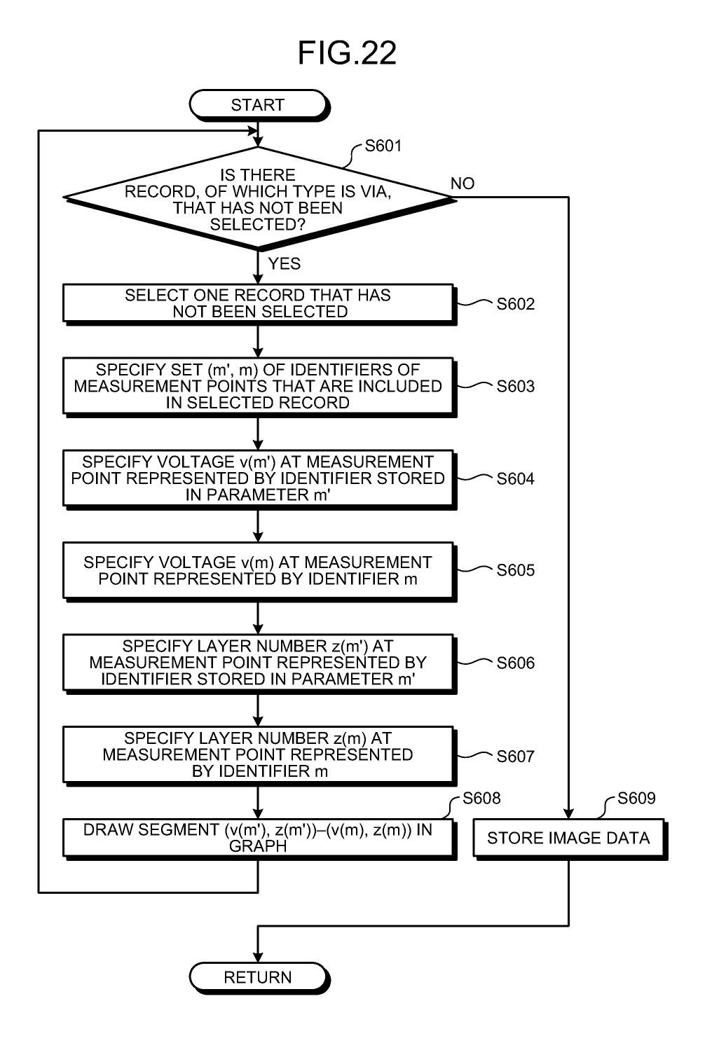

FIG. 22 is a flowchart that illustrates the sequence of a via voltage drop drawing process according to the first embodiment. As illustrated in FIG. 22, the drawing unit 14c determines whether or not there is a record that has not been selected out of records in which the via is registered in the entry in which the type of an element is registered in the connection table 13d in Step S601. In a case where there is a record that has not been selected (Yes in Step S601), the drawing unit 14c selects one record that has not been selected in Step S602. Then, the drawing unit 14c specifies a set (m′, m) of identifiers of measurement points that are included in the selected record in Step S603. Thereafter, the drawing unit 14c specifies a voltage v(m′) at the measurement point that is represented by the identifier stored in parameter m′ from the measurement point table 13c in Step S604. Subsequently, the drawing unit 14c specifies a voltage v(m) at the measurement point represented by the identifier m from the measurement point table 13c in Step S605. Then, the drawing unit 14c specifies a layer number z(m′) of a layer in which the measurement point represented by the identifier that is stored in parameter m′ is present from the measurement point table 13c in Step S606. Subsequently, the drawing unit 14c specifies a layer number z(m) of the layer in which the measurement point represented by the identifier m is present from the measurement point table 13c in Step S607. Thereafter, the drawing unit 14c draws a segment (v(m′), z(m′))-(v(m), z(m)) in the drawing area of the graph in Step S608, and the process is returned to Step S601.

On the other hand, in a case where there is no record that has not been selected (No in Step S601), the drawing unit 14c stores the image data 13e of the graph in the storage unit 13 in Step S609 and stores the processing result in the internal memory, and the process is returned.

As described above, the drawing device 10 according to this embodiment draws the appearance of a voltage drop of each plane on a graph in which the voltage is set on the X axis, and the layer is set on the Y axis. Then, the drawing device 10 performs control so as to display the drawn graph. Therefore, according to the drawing device 10, it can be controlled to display an image from which the appearance of a voltage drop of each plane in the laminated circuit board can be easily perceived.

In addition, the drawing device 10 according to this embodiment draws the appearance of a voltage drop of each via on a graph in which the voltage is set on the X axis, and the layer is set on the Y axis. Therefore, according to the drawing device 10, it can be controlled to display an image from which the appearance of a voltage drop of each via in the laminated circuit board can be easily perceived.

### [b] Second Embodiment

In a second embodiment, a case will be described in which information representing the magnitude of a current flowing through a via is drawn on a graph.

Configuration of Drawing Device 30

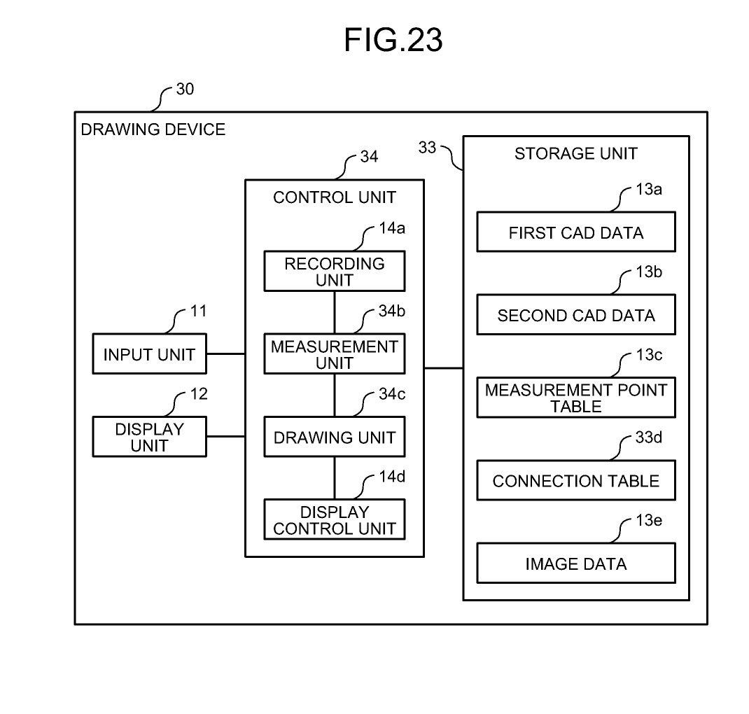

FIG. 23 is a diagram that illustrates an example of the functional configuration of a drawing device according to the second embodiment. As illustrated in FIG. 23, a drawing device 30 includes a storage unit 33 and a control unit 34. A difference between the stored contents of the storage unit 33 and the storage unit 13 according to the first embodiment illustrated in FIG. 1 is that a connection table 33d is stored instead of the connection table 13d in the storage unit 33. In addition, a difference between the control unit 34 and the control unit 14 according to the first embodiment illustrated in FIG. 1 is that a measurement unit 34b and a drawing unit 34c are included in the control unit 34. Hereinafter, the same reference numeral as that illustrated in FIG. 1 is assigned to each unit or each device that achieves the same function as that of the first embodiment, and the description thereof will not be presented.

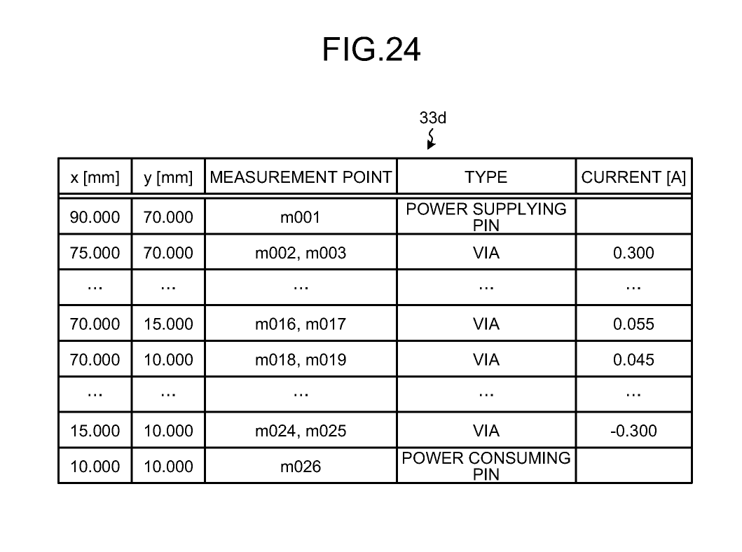

FIG. 24 is a diagram that illustrates an example of the data structure of the connection table according to the second embodiment. In the connection table 33d illustrated in the example represented in FIG. 24, the value of a current i [A] flowing between two measurement points of the same via is registered by the measurement unit 34b to be described below, in addition to the registered content of the connection table 13d according to the first embodiment. The example represented in FIG. 24 illustrates that a current of 0.300 [A] flows between two measurement points of a via that has the two measurement points represented by two identifiers m002 and m003. The other vias are similarly applied.

The storage unit 33, for example, is a semiconductor memory device such as a flash memory or a storage device such as a hard disk or an optical disc. The storage unit 33 is not limited to the storage device of a type described above and may be a random access memory (RAM) or a read only memory (ROM).

The measurement unit 34b has a function of performing a process as follows in addition to the functions of the measurement unit 14b according to the first embodiment. That is, for each set (m′, m) of all the identifiers in which identifiers are registered as the set (m′, m) in the connection table 33d, the measurement unit 34b measures a current i between measurement points that correspond to the set (m′, m). Subsequently, the measurement unit 34b determines whether or not there is a set (m′, m) that has not been selected out of sets (m′, m) of identifiers that are registered in the connection table 33d. In a case where there is a set (m′, m) that has not been selected, the measurement unit 34b selects one set (m′, m) that has not been selected out of sets (m′, m) of the identifiers that are registered in the connection table 33d. Then, the measurement unit 34b registers the current i between two measurement points represented by the set (m′, m) of selected identifiers in the connection table 33d in association with the set (m′, m) of the selected identifiers. As a result, as illustrated in the example represented in FIG. 24, the magnitude of a current flowing through two measurement points included in the via is registered in the connection table 33d. The measurement unit 34b repeatedly performs such a process until there is no set (m′, m) that has not been selected.

The drawing unit 34c determines whether or not there is a record that has not been selected out of records in which the via is recorded in the entry in which the type of an element is recorded in the connection table 33d. In a case where there is a record that has not been selected, the drawing unit 34c selects one record that has not been selected. Then, the drawing unit 34c specifies a set (m′, m) of identifiers of measurement points that are included in the selected record. Thereafter, the drawing unit 34c specifies a voltage v(m′) at the measurement point that is represented by the identifier stored in parameter m′ from the measurement point table 13c. In addition, the drawing unit 34c specifies a voltage v(m) at the measurement point that is represented by the identifier m from the measurement point table 13c. Furthermore, the drawing unit 34c specifies a layer number z(m′) of a layer in which a measurement point represented by the identifier stored in parameter m′ is present from the measurement point table 13c. In addition, the drawing unit 34c specifies a layer number z(m) of a layer in which the measurement point represented by the identifier m is present from the measurement point table 13c. Thereafter, the drawing unit 34c specifies a current i between two measurement points corresponding to the set (m′, m) of the identifiers of the measurement points from the connection table 33d. Then, the drawing unit 34c determines a thickness for drawing based on the magnitude of the specified current i. For example, the drawing unit 34c determines such that, the larger the magnitude of the current i is, the larger the thickness for drawing is.

Subsequently, the drawing unit 34c determines a direction in which the current i flows based on the magnitude relation of voltages v(m′) and v(m). Then, the drawing unit 34c performs drawing for the drawing area of the graph such that a segment (v(m′), z(m′))-(v(m), z(m)) is an arrow representing the direction in which the current i flows and has a thickness that is determined for drawing a line. The drawing unit 34c repeatedly performs such a process until there is no record that has not been selected out of records in which the via is registered in the entry in which the type of an element is registered in the connection table 33d. Then, in a case where there is no record that has not been selected, the drawing unit 34c stores the image data 13e of the graph for which the drawing process is performed in the storage unit 33.

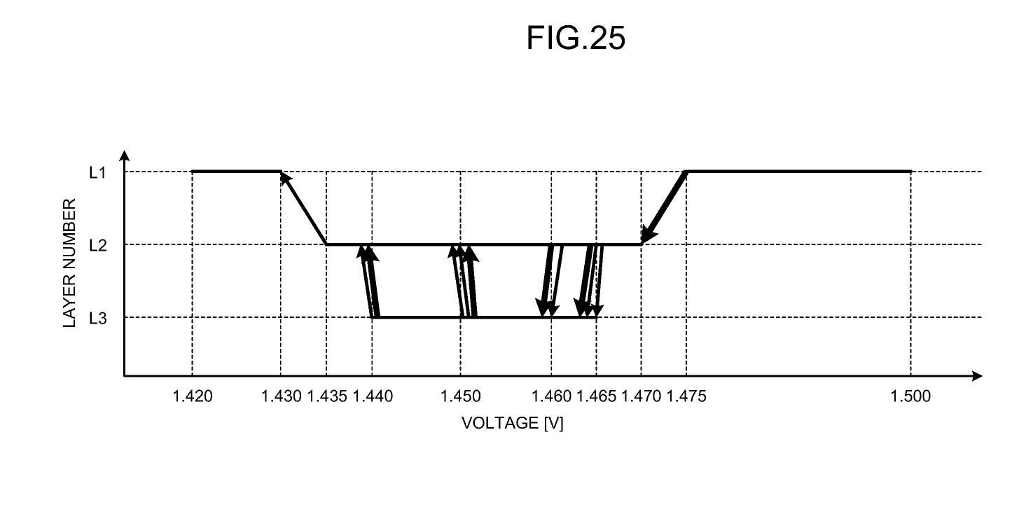

FIG. 25 is a diagram that illustrates an example of a segment that represents the magnitude of a current flowing through a via that is drawn by the drawing unit. As illustrated on the graph of the example represented in FIG. 25, the thickness of a segment that corresponds to a via portion corresponds to the magnitude of the current. Accordingly, the magnitude of the current flowing through each via in the laminated circuit board can be perceived from the graph in an easy manner.

In this way, the drawing device 30 according to this embodiment draws a segment that represents the magnitude of the current flowing through each via on the graph in which the voltage is set on the X axis, and the layer is set on the Y axis. Therefore, according to the drawing device 30, an image can be presented from which the appearance of the magnitude of the current flowing through each via in the laminated circuit board can be perceived in an easy manner. In addition, the drawing unit 34c may determine a color of a segment that corresponds to the magnitude of the current i based on the magnitude of the current i and perform drawing such that the color of the segment (v(m′), z(m′))-(v(m), z(m)) is a determined color.

The control unit 34 is an integrated circuit such as an ASIC or an FPGA or an electronic circuit such as a CPU or an MPU.

Flow of Process

Next, the flow of the process performed by the drawing device 30 according to this embodiment will be described. The process contents of a measurement process and a via voltage drop drawing process according to this embodiment are different from those of the measurement process and the via voltage drop drawing process according to the first embodiment illustrated in FIG. 16.

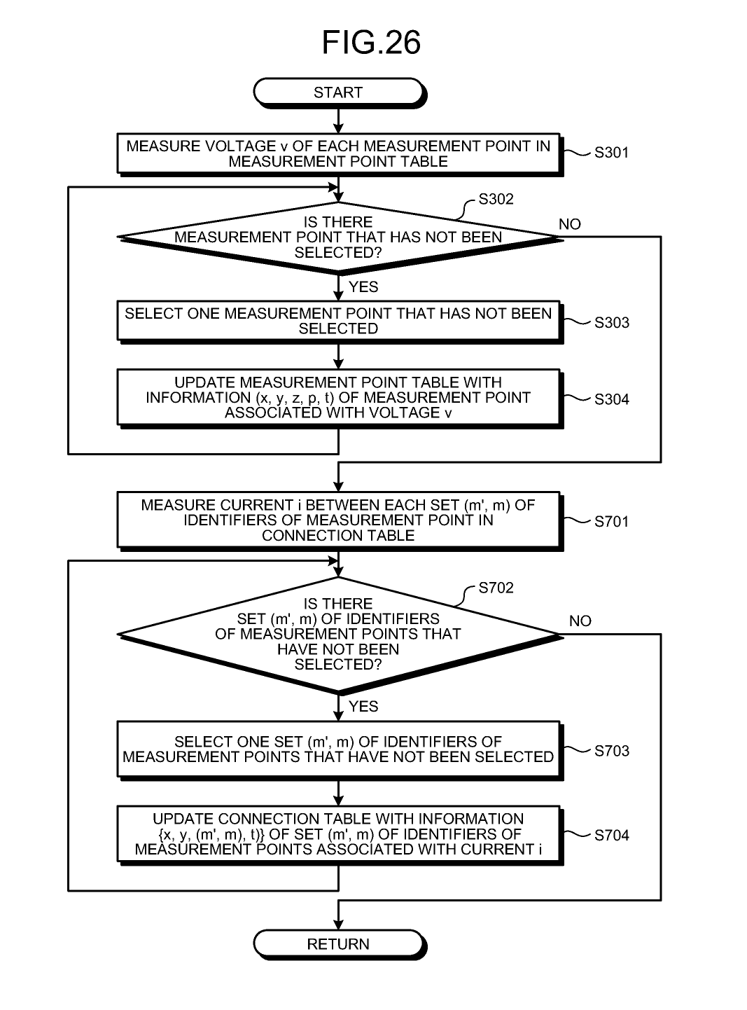

FIG. 26 is a flowchart that illustrates the sequence of the measurement process according to the second embodiment. As illustrated in FIG. 26, the processes of steps S301 to S304 are the same as those of the first embodiment. In Step S302, in a case where it is determined that there is no measurement point that has not been selected (No in Step S302), for each set (m′, m) of all the identifiers in which the identifiers are registered as the set (m′, m) in the connection table 33d, the measurement unit 34b measures a current i between measurement points that correspond to the set (m′, m) in Step S701.

Subsequently, the measurement unit 34b determines whether or not there is a set (m′, m) that has not been selected out of the sets (m′, m) of identifiers registered in the connection table 33d in Step S702. In a case where there is no set (m′, m) that has not been selected (No in Step S702), the measurement unit 34b stores the process result in an internal memory, and the process is returned. On the other hand, in a case where there is a set (m′, m) that has not been selected (Yes in Step S702), the measurement unit 34b selects one set (m′, m) that has not been selected out of the sets (m′, m) of identifiers that are registered in the connection table 33d in Step S703. Then, the measurement unit 34b registers the current between two measurement points represented by the selected set (m′, m) of the identifiers in the connection table 33d in association with the selected set (m′, m) of the identifiers in Step S704, and the process is returned to Step S702.

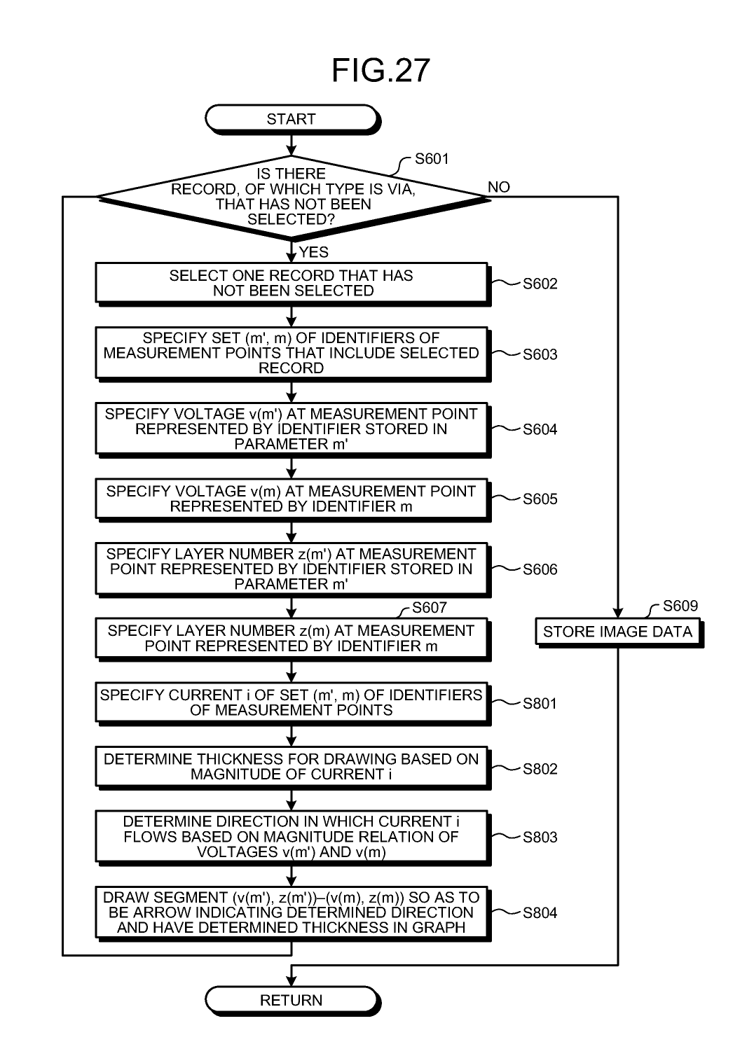

FIG. 27 is a flowchart that illustrates the sequence of a via voltage drop drawing process according to the second embodiment. As illustrated in FIG. 27, the processes of Steps S601 to S607 and S609 are the same as those of the first embodiment. As illustrated in FIG. 27, after the process of Step S607, the drawing unit 34c specifies a current i between two measurement points that correspond to a set (m′, m) of identifiers of the measurement points from the connection table 33d in Step S801. Then, the drawing unit 34c determines a thickness for drawing based on the magnitude of the specified current i in Step S802.

Subsequently, the drawing unit 34c determines a direction in which the current i flows based on the magnitude relation of voltages v(m′) and v(m) in Step S803. Then, the drawing unit 34c performs drawing for the drawing area of the graph such that a segment (v(m′), z(m′))-(v(m), z(m)) is an arrow that represents the direction in which the current i flows and has a determined thickness for drawing a line in Step S804, and the process is returned to Step S601.

As described above, the drawing device 30 according to this embodiment draws the appearance of a voltage drop of each plane on a graph having the voltage set on the X axis and having the layer set on the Y axis. Then, the drawing device 30 performs control so as to display the drawn graph. Therefore, according to the drawing device 30, it can be controlled to display an image from which the appearance of a voltage drop of each plane in the laminated circuit board can be perceived in an easy manner.

In addition, the drawing device 30 according to this embodiment draws the appearance of a voltage drop of each via on a graph having the voltage set on the X axis and having the layer set on the Y axis. Therefore, according to the drawing device 30, it can be controlled to display an image from which the appearance of a voltage drop of each via in the laminated circuit board can be perceived in an easy manner.

Furthermore, the drawing device 30 according to this embodiment draws a segment that represents the magnitude of a current flowing through each via in a thickness or a color on a graph having the voltage set on the X axis and having the layer set on the Y axis. Therefore, according to the drawing device 30, it can be controlled to display an image from which the appearance of the magnitude of a current of each via in the laminated circuit board can be perceived in an easy manner.

### [c] Third Embodiment

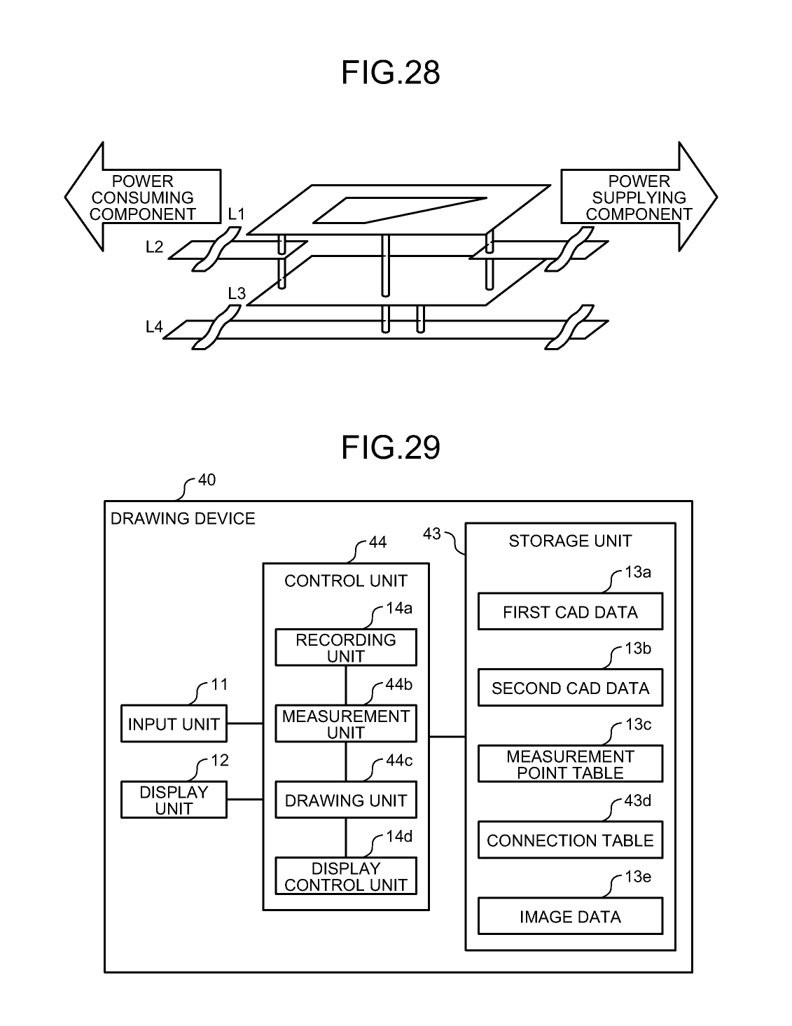

In a third embodiment, a case will be described in which information representing the magnitude of a current flowing through a plane is drawn on a graph. FIG. 28 is a schematic diagram of a laminated circuit board in a case where there is a plurality of paths joining two points in a net and the paths go through planes that are different from each other. The laminated circuit board illustrated in the example represented in FIG. 28 includes a plane of layer number L1 and a plane of layer number L3 in which almost the same voltage drop occurs. In such a case, in the third embodiment, by presenting the magnitudes of a current flowing through the plane of layer number L1 and a current flowing through the plane of layer number L3 in which the voltage drops are the same, it can be perceived that the resistance of the plane of one layer is higher than that of the other layer.

Configuration of Drawing Device 40

FIG. 29 is a diagram that illustrates an example of the functional configuration of a drawing device according to the third embodiment. As illustrated in FIG. 29, a drawing device 40 includes a storage unit 43 and a control unit 44. A difference between the storage unit 43 and the storage unit 33 according to the second embodiment illustrated in FIG. 23 is that a connection table 43d is stored in the storage unit 43. In addition, a difference between the control unit 44 and the control unit 34 according to the second embodiment illustrated in FIG. 23 is that a measurement unit 44b and a drawing unit 44c are included in the control unit 44. Hereinafter, the same reference numeral as that illustrated in FIG. 1 or FIG. 23 is assigned to each unit or each device that achieves the same function as that of the first embodiment or the second embodiment described above, and the description thereof will not be presented.

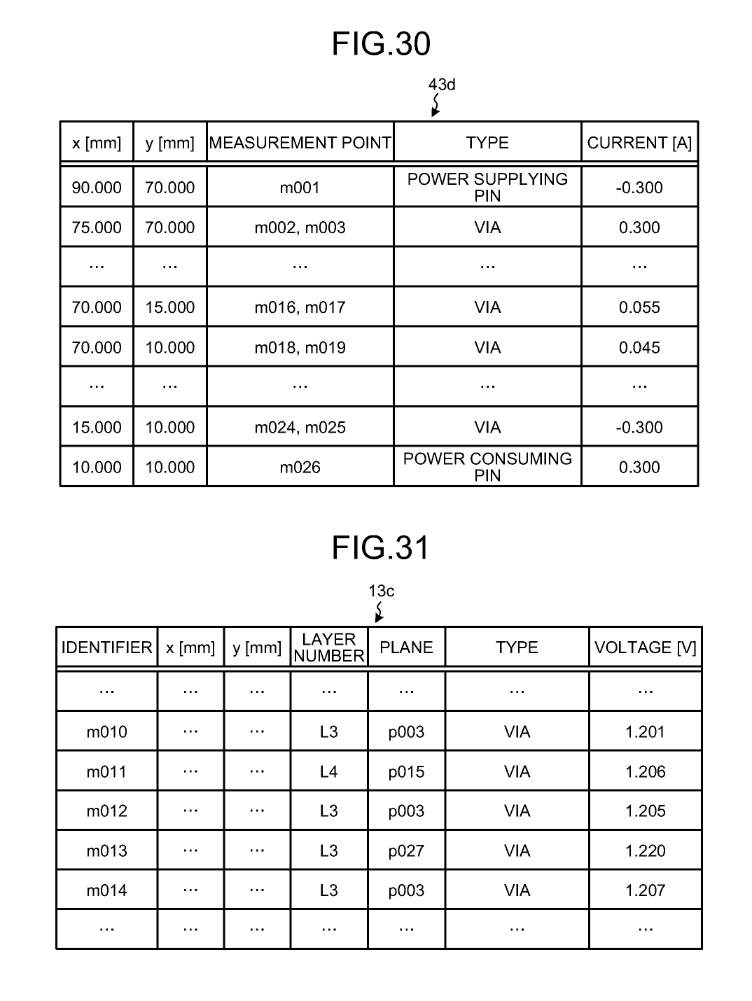

FIG. 30 is a diagram that illustrates an example of the data structure of a connection table according to the third embodiment. In the connection table 43d of the example represented in FIG. 30, a value of a current i [A] flowing through the measurement point of the power supplying pin and a measurement point of the power consuming pin is registered by the measurement unit 44b in addition to the registered content of the connection table 33d according to the second embodiment. In the example represented in FIG. 30, a case is illustrated in which a current of −0.300 [A] flows through the measurement point of the power supplying pin and a current of 0.300 [A]flows through the measurement point of the power consuming pin. In addition, the value of a current i [A] that flows through the measurement point of the power supplying pin and the measurement point of the power consuming pin is assumed to be input by a user using the drawing device 40 through an input unit 11.

The storage unit 43, for example, is a semiconductor memory device such as a flash memory or a storage device such as a hard disk or an optical disc. The storage unit 33 is not limited to the storage device of a type described above and may be a random access memory (RAM) or a read only memory (ROM).

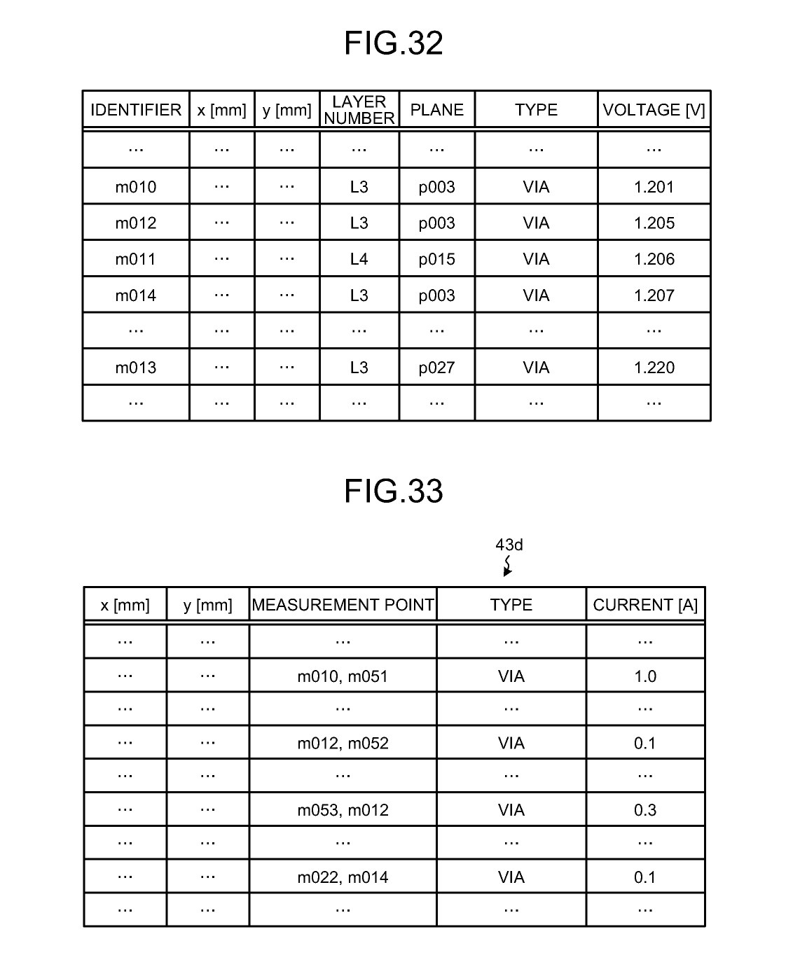

The measurement unit 44b has a function of performing a process as follows in addition to the functions of the measurement unit 34b according to the second embodiment. The measurement unit 44b registers a value of a current i [A] that flows through the measurement point of the power supplying pin and the measurement point of the power consuming pin that is input through the input unit 11 in the connection table 43d. In addition, the measurement unit 44b generates a table (sorted table) that is acquired by sorting the measurement point table 13c with respect to the voltage v in the ascending order. FIGS. 31 and 32 are diagrams that illustrate an example of a method of generating the sorted table. FIG. 31 is a diagram that illustrates an example of the measurement point table 13c. FIG. 32 is a sorted table that is acquired as a result of sorting the measurement point table 13c illustrated in the example represented in FIG. 31 with respect to the voltage v in the ascending order. For example, the measurement unit 44b sorts the measurement point table 13c with respect to the voltage v in the ascending order using the measurement point table 13c illustrated in the example represented in FIG. 31, thereby generating the sorted table that is illustrated in the example represented in FIG. 32. Subsequently, the measurement unit 44b sets the value of parameter is(p) in which a current value is stored to zero for all the planes p.

Then, the measurement unit 44b determines whether or not there is a measurement point that has not been selected by referring to the sorted table. In a case where there is a measurement point that has not been selected, the measurement unit 44b selects a measurement point, which has not been selected, that is a measurement point m1 having a lowest voltage v out of measurement points of which voltages v are sorted in the ascending order. In addition, the measurement unit 44b can select a plurality of measurement points in a case where there is a plurality of measurement points having the same values of voltages v. Thereafter, the measurement unit 44b specifies a measurement point m2 having a voltage v that is higher than that at the measurement point m1 and is closest to the voltage at the measurement point m1 out of the other measurement points in the plane p having the measurement point m1. For example, a case will be described in which the sorted table illustrated in the example represented in FIG. 32 is used. The measurement unit 44b performs a process as follows in a case where a measurement point represented by an identifier m010 illustrated in the example represented in FIG. 32 is selected. The measurement unit 44b specifies a measurement point of an identifier m012 having a voltage that is higher than a voltage 1.201 [V] and is closest to the voltage 1.201 [V] out of the other measurement points (measurement points of identifiers m012 and m014) in a plane (plane p003) that includes the measurement point of the identifier m010.

Subsequently, the measurement unit 44b determines whether or not the measurement point m2 is specified. In a case where the measurement point m2 is not specified, the above-described process of determining whether or not there is a measurement point that has not been selected is performed again, and, as described above, the subsequent processes after the process of determining whether or not there is a measurement point that has not been selected are performed again.

On the other hand, in a case where the measurement point m2 is specified, the measurement unit 44b adds a sum of a current flowing into the measurement point m1 of the plane p and a current flowing out of the measurement point m1 to the value of is(p), thereby updating the value of is(p).

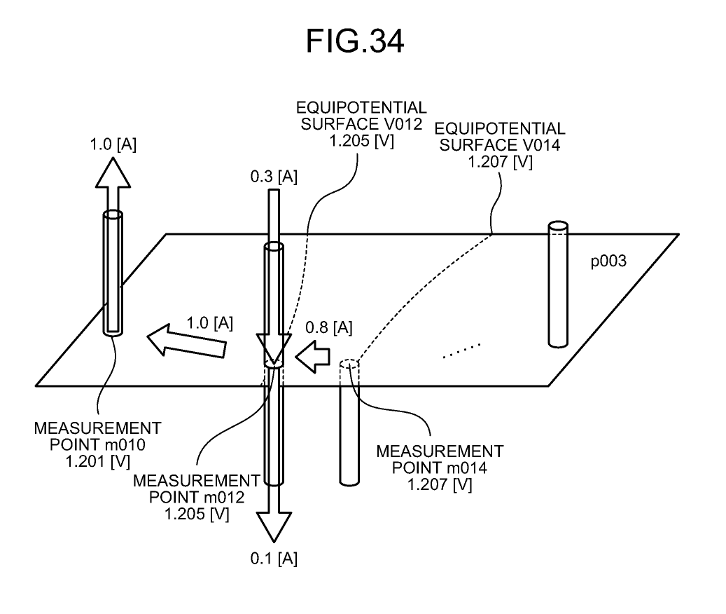

A specific example will be described. FIG. 33 is a diagram that illustrates an example of the connection table. FIG. 34 is a schematic diagram that illustrates some vias and some planes that are represented by the sorted table illustrated in the example represented in FIG. 32. A case will be described in which the measurement unit 44b selects a measurement point represented by an identifier m010 by referring to the sorted table illustrated in the example represented in FIG. 32. In such a case, the measurement unit 44b, as illustrated in the example represented in FIG. 34, specifies a measurement point (a measurement point of which the identifier is m012) that has a lowest voltage next to a measurement point (a measurement point of which the identifier is m010) of the lowest voltage 1.201 [V] for the plane represented by the identifier p003. The voltage at the measurement point of which the identifier is m012 is 1.205 [V], and an equipotential surface of a voltage 1.205 [V] is present in the plane represented by the identifier p003. Here, by referring to the connection table 43d illustrated in the example represented in FIG. 33, a record in which the measurement point of the identifier m010 is registered is located in the first row. Here, a current of 1.0 [A] flows from the measurement point of which the identifier is m010 to the measurement point of which the identifier is m051. In other words, a current of 1.0 [A] flows in a direction flowing out from the plane represented by the identifier p003. In such a case, the measurement unit 44b adds a positive value “1.0” to the value of is(p003)=0, thereby updating the value of is(p003)=1.0. Here, is(p003) after the update represents a magnitude of a current flowing into the measurement point m010 from the plane represented by the identifier p003. In the plane represented by the identifier p003, the voltage exceeds the voltage of the measurement point m010, and flowing in/out of a current at a point having a voltage lower than the voltage of the equipotential surface that is the voltage of 1.205 [V] does not occur, and accordingly, is(p003) after the update represents a passing current from the equipotential surface of the measurement point m012 to the measurement point m010.

In addition, the measurement unit 44b performs a process as follows by referring to the measurement point table 13c. The measurement unit 44b selects a measurement point (measurement point m012) having a voltage that is lowest next to the voltage at the measurement point m010 in the plane represented by the identifier p003 and specifies a measurement point (measurement point m014) having a voltage that is lowest next to the voltage at the measurement point m012. The voltage at the measurement point m014 is 1.207 [V], and an equipotential surfaces having a voltage of 1.205 [V] is present on the plane that is represented by the identifier p003. Here, there are two records in which measurement point m012 is registered when the connection table 43d illustrated in the example represented in FIG. 33 is referred to. The first record represents that a current of 0.1 [A] flows from the measurement point m012 to the measurement point m052. In other words, the first record represents that a current flows in a direction (the direction in which the current flows into the via) in which the current flows out from the plane represented by the identifier p003. The second record represents that a current of 0.3 [A] flows from measurement point m053 to the measurement point m012. In other words, the second record represents that a current flows in a direction (a direction in which the current flows out from the via) in which the current flows into the plane represented by the identifier p003.

Here, a current flowing out from the plane is denoted as negative sign, and a current flowing into the plane is denoted by a positive sign. The measurement unit 44b adds to is(p003) a value acquired by adding these currents, thereby updating the value. In other words, the measurement unit 44b updates the value to is(p003)=1.0−0.3+0.1=0.8 [A]. In the plane represented by the identifier p003, the voltage exceeds the voltage of the measurement point m012, and flowing in/out of a current at a point having a voltage lower than the voltage of the equipotential surface that is the voltage of 1.207 [V] does not occur, and accordingly, is(p003) after the update represents a passing current that passes from the equipotential surface of the measurement point m014 to the equipotential surface of the measurement point m012.

The measurement unit 44b performs the above-described process for all the planes with measurement points having voltages close to each other used as a pair within the same plane, whereby the magnitude of a current flowing through the plane can be measured.

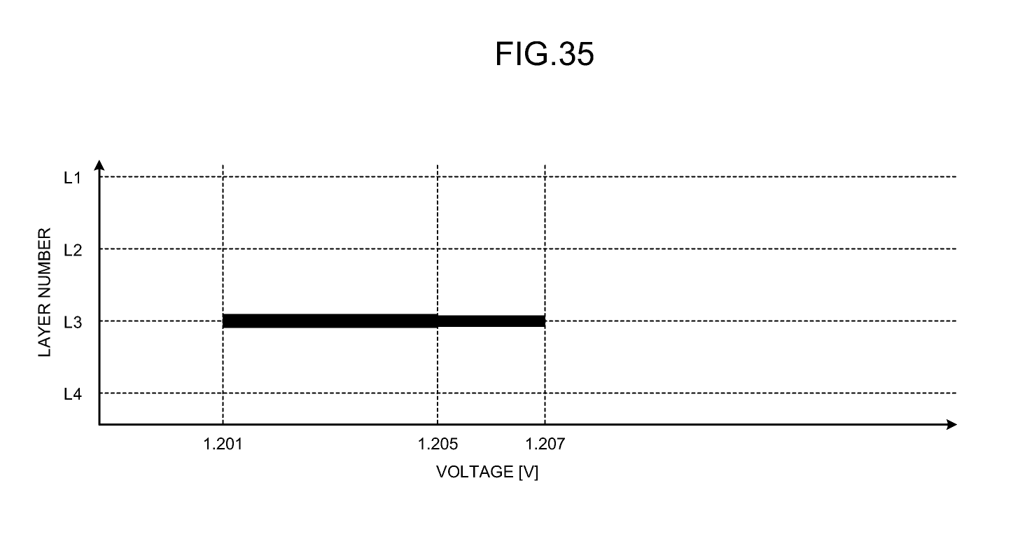

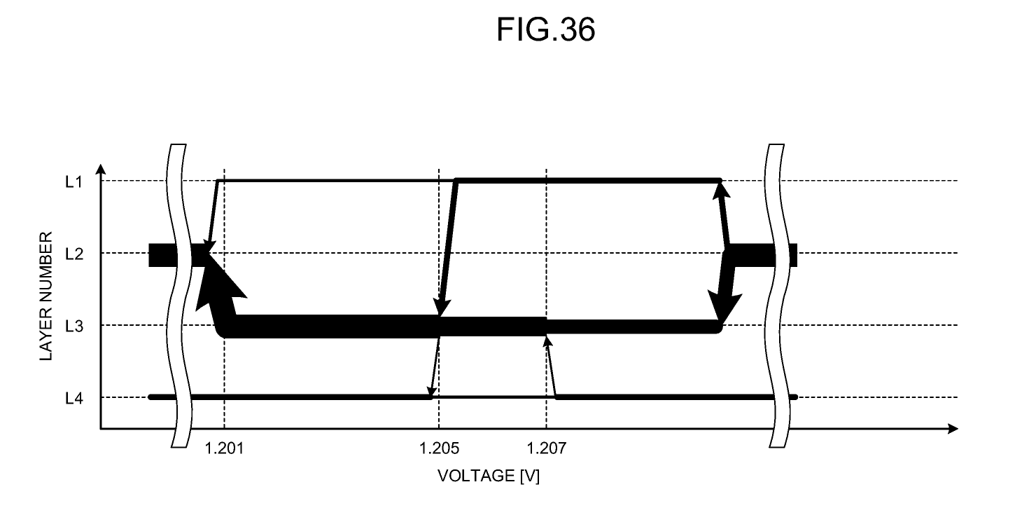

The drawing unit 44c draws a segment (v(m1), z)-(v(m2), z) with a thickness that corresponds to the magnitude of the current value is(p) on a graph. For example, a case will be described in which a value of is(p003) that corresponds to a segment (1.201, L3)-(1.205, L3) is 1.0 [A], and a value of is(p003) that corresponds to a segment (1.205, L3)-(1.207, L3) is 0.8 [A]. In such a case, in a case where a thickness of the segment (1.201, L3)-(1.205, L3) is set to “1”, the drawing unit 44c draws the segment (1.205, L3)-(1.207, L3) with a thickness of “0.8”. FIGS. 35 and 36 are diagrams that illustrate examples of the thickness of a segment that is drawn by the drawing unit. In the example represented in FIG. 35, a case is illustrated in which, in a case where a thickness of the segment (1.201, L3)-(1.205, L3) is set to “1”, the drawing unit 44c draws the segment (1.205, L3)-(1.207, L3) with a thickness of “0.8”.

The example represented in FIG. 36 illustrates currents flowing through each plane of each layer in the laminated circuit board that is illustrated in the example represented in FIG. 28. In the example represented in FIG. 36, it can be easily perceived that the resistance of a plane, of which the layer number is L1, having a thinner segment is higher than the resistance of a plane of which the layer number is L3.

In addition, the drawing device 40 according to this embodiment draws a segment that represents the magnitude of the current flowing through each plane using a thickness or a color on a graph having the voltage set on the X axis and having the layer set on the Y axis. Therefore, according to the drawing device 40, it can be controlled to display an image from which the appearance of the magnitude of a current flowing through each plane in the laminated circuit board can be perceived in an easy manner.

The control unit 44 is an integrated circuit such as an ASIC or an FPGA or an electronic circuit such as a CPU or an MPU.

Flow of Process

Next, the flow of the process performed by the drawing device 40 according to this embodiment will be described. The process content of a plane voltage drop drawing process according to this embodiment is different from that of the plane voltage drop drawing process according to the first embodiment illustrated in FIG. 16.

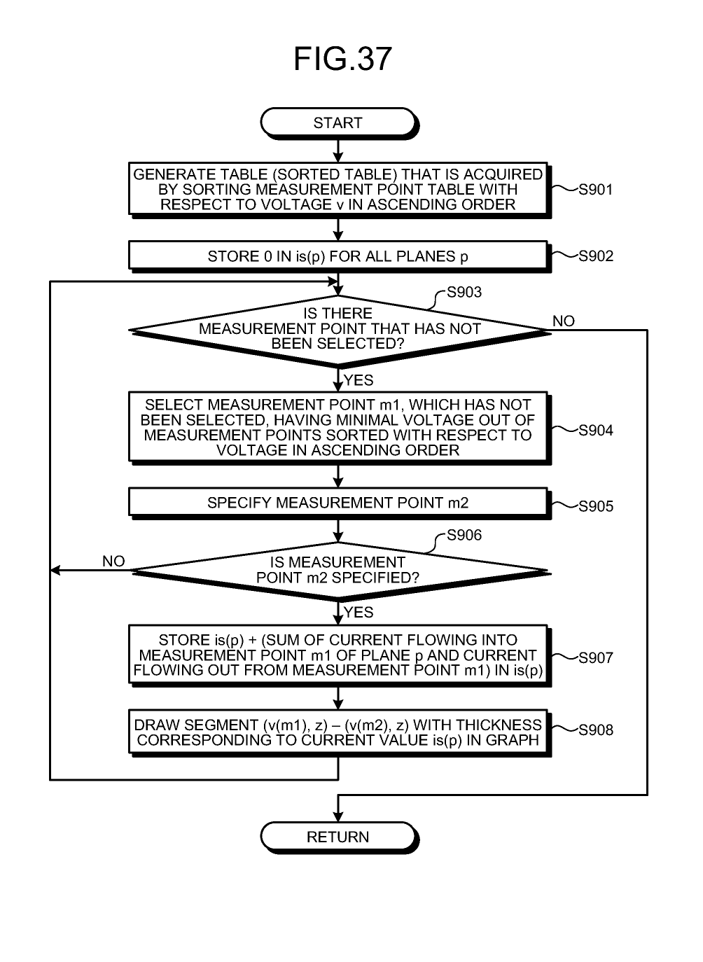

FIG. 37 is a flowchart that illustrates the sequence of the plane voltage drop drawing process according to the third embodiment. As illustrated in FIG. 37, the measurement unit 44b generates a table (sorted table) acquired by sorting the measurement point table 13c with respect to the voltage v in the ascending order in Step S901. Subsequently, the measurement unit 44b sets the value of parameter is(p) in which a current value is stored to zero for all the planes p in Step S902.

Then, the measurement unit 44b determines whether or not there is a measurement point that has not been selected by referring to the sorted table in Step S903. In a case where there is no measurement point that has not been selected (No in Step S903), the measurement unit 44b stores the process result in an internal memory, and the process is returned. On the other hand, in a case where there is a measurement point that has not been selected (Yes in Step S903), the measurement unit 44b selects a measurement point m1 that has not been selected and has a lowest voltage v out of the measurement points that are sorted with respect to the voltage v in the ascending order in Step S904. Thereafter, the measurement unit 44b specifies a measurement point m2 having a voltage v that is higher than the voltage at the measurement point m1 and is closest to the voltage at the measurement point m1 out of the other measurement points in the plane p that includes the measurement point m1 in Step S905.

Subsequently, the measurement unit 44b determines whether or not the measurement point m2 is specified in Step S906. In a case where the measurement point m2 is not specified (No in Step S906), the process is returned to Step S903.

On the other hand, in a case where the measurement point m2 is specified (Yes in Step S906), the measurement unit 44b adds a sum of the current flowing into the measurement point m1 of the plane p and the current flowing out from the measurement point m1 to the value of is(p), thereby updating the value of is(p) in Step S907.

Then, the drawing unit 44c draws a segment (v(m1), z)-(v(m2), z) with a thickness that corresponds to the magnitude of the current value is(p) on a graph in Step S908, and the process is returned to Step S903.

As described above, the drawing device 40 according to this embodiment draws the appearance of a voltage drop of each plane on the graph having the voltage set on the X axis and having the layer set on the Y axis. Then, the drawing device 40 performs control such that the drawn graph is displayed. Therefore, according to the drawing device 40, control can be performed such that an image from which the appearance of a voltage drop of each plane in the laminated circuit board can be easily perceived is displayed.

In addition, the drawing device 40 according to this embodiment draws the appearance of a voltage drop of each via on a graph in which the voltage is set on the X axis and the layer is set on the Y axis. Therefore, according to the drawing device 40, control can be performed such that an image from which the appearance of a voltage drop of each via in the laminated circuit board can be easily perceived is displayed.

Furthermore, the drawing device 40 according to this embodiment draws a segment that represents the magnitude of a current of each via in a thickness or a color on a graph having the voltage set on the X axis and having the layer set on the Y axis. Therefore, according to the drawing device 40, control can be performed such that an image from which the appearance of the magnitude of a current of each via in the laminated circuit board can be easily perceived is displayed.

In addition, the drawing device 40 according to this embodiment draws a segment that represents the magnitude of a current flowing through each plane in a thickness or a color on a graph having the voltage set on the X axis and having the layer set on the Y axis. Therefore, according to the drawing device 40, it can be controlled to display an image from which the appearance of the magnitude of a current of each plane in the laminated circuit board can be perceived in an easy manner.

Until now disclosed devices according to embodiments have been described. However, the present invention may be performed in various embodiments other than the above-described embodiments. Hereinafter, other embodiments belonging to the present invention will be described.

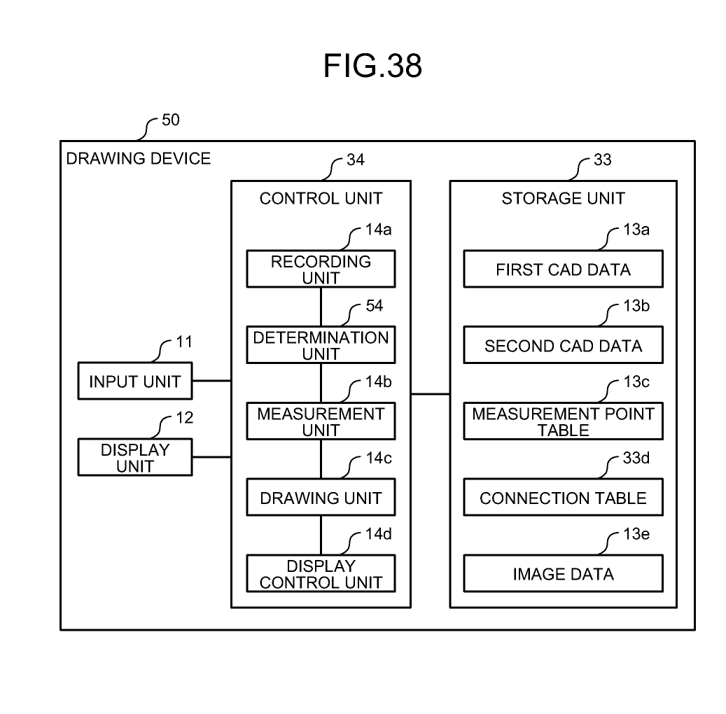

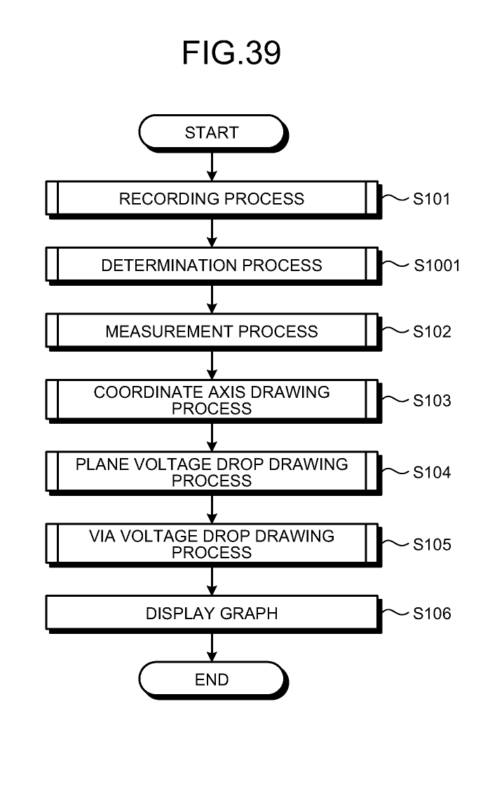

For example, whether a connection relation of measurement points in each embodiment is appropriate in the context of a display, in other words, a net connected to the power supplying pin is connected to the power consuming pin, and a determination process of determining whether the path of a voltage drop is present may be performed. FIG. 38 is a diagram that illustrates an example of the functional configuration of a drawing device acquired by adding a function of the determination process to the drawing device according to each embodiment. The example represented in FIG. 38 illustrates a case where a determination unit 54d is added to the drawing device 10 according to the first embodiment. In addition, the determination unit 54d may be disposed in the drawing device according to the second or third embodiment. FIG. 39 is a flowchart that illustrates the sequence of a drawing process to which the determination process is added. As illustrated in FIG. 39, after the recording process, the determination unit 54d performs the determination process in Step S1001. Then, the process proceeds to the measurement process.

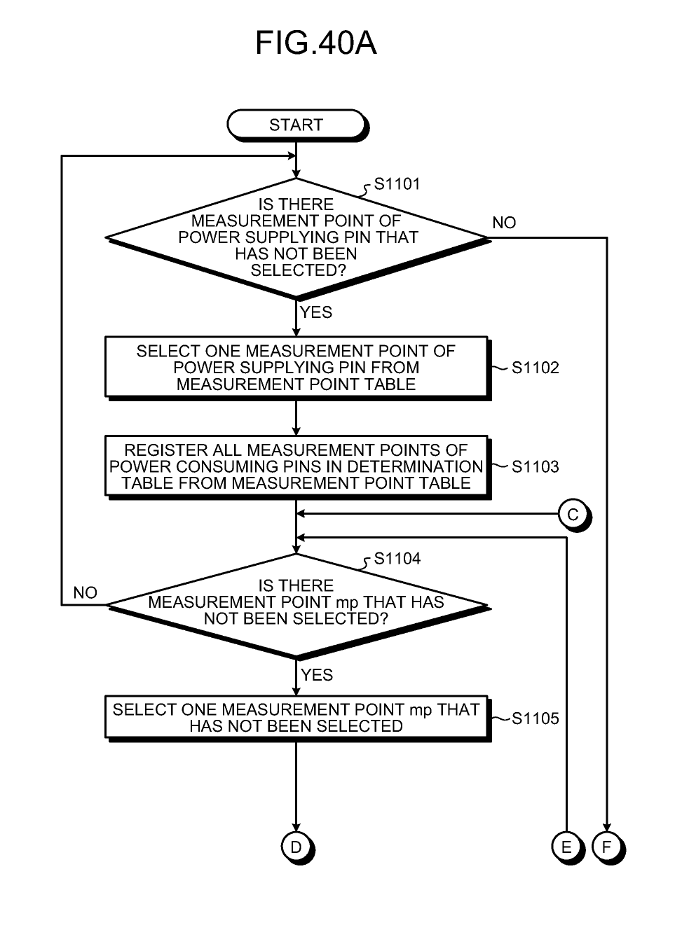

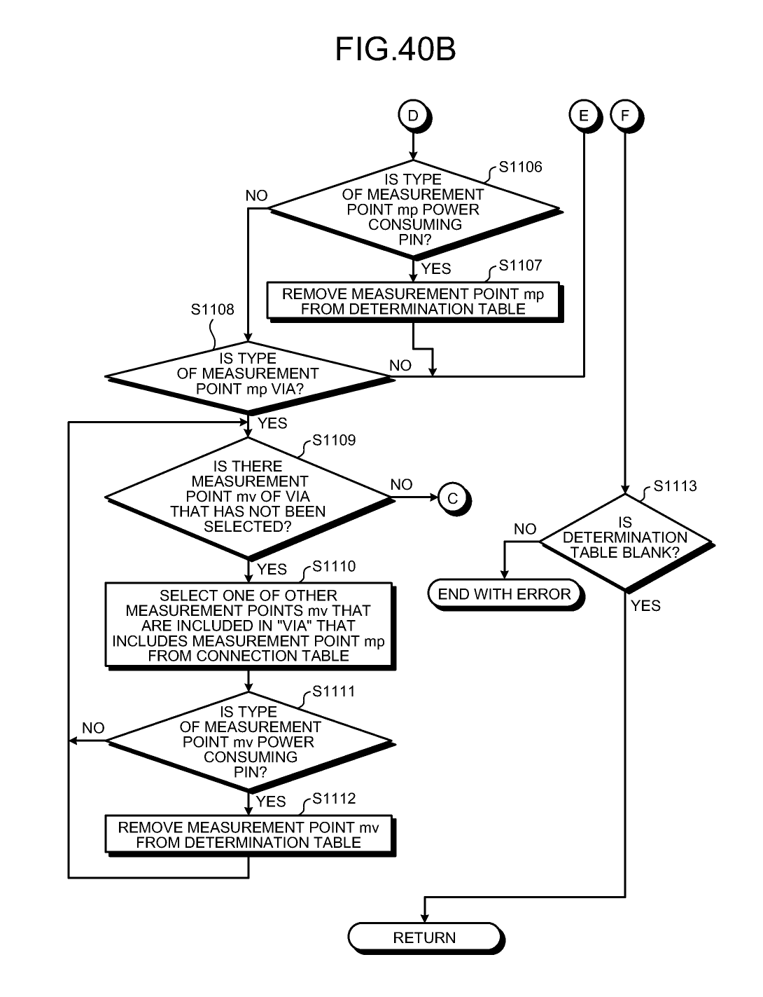

FIGS. 40A and 40B are flowcharts that illustrate the sequence of the determination process. As illustrated in FIGS. 40A and 40B, the determination unit 54d determines whether or not there is a measurement point of which the type of the element in the measurement point table 13c is the power supplying pin in Step S1101. In a case where there is no measurement point of which the type of the element is the power supplying pin (No in Step S1101), a determination unit 54 determines whether or not a determination table to be described later is blank in Step S1113. In a case where the determination table is not blank, the process ends with an error, and the drawing process is stopped. On the other hand, in a case where the determination table is blank, the determination unit 54 stores the process result in an internal memory, and the process is returned.

On the other hand, in a case where there is a measurement point of which the type of the element is the power supplying pin (Yes in Step S1101), the determination unit 54 selects one measurement point, of which the type of the element is the power supplying pin, that has not been selected in the measurement point table 13c in Step S1102. Subsequently, the determination unit 54 registers all the measurement points of which the types of elements are the power consuming pins in the measurement point table 13c in Step S1103.

The determination unit 54 determines whether or not there is a measurement point mp that has not been selected out of measurement points mp that are present within the same plane as that of the selected measurement point in the measurement point table 13c in Step S1104. In a case where there is no measurement point mp that has not been selected (No in Step S1104), the process is returned to Step S1101. On the other hand, in a case where there is a measurement point mp that has not been selected (Yes in Step S1104), the determination unit 54 selects one measurement point mp that has not been selected and is within the same plane as that of the selected measurement point in Step S1105. Then, the determination unit 54 determines whether or not the type of the element including the selected measurement point mp is the power consuming pin in Step S1106. In a case where the type of the element is the power consuming pin (Yes in Step S1106), the determination unit 54 removes the selected measurement point mp from the determination table in Step S1107, and the process is returned to Step S1104.

On the other hand, in a case where the type of the element is not the power consuming pin (No in Step S1106), the determination unit 54 determines whether or not the type of the element including the selected measurement point mp is the via in Step S1108. In a case where the type of the element is not the via (No in Step S1108), the process is returned to Step S1104. On the other hand, in a case where the type of the element is the via (Yes in Step S1108), the determination unit 54 determines whether or not there is a measurement point my that has not been selected out of the other measurement points my included in the via that includes the selected measurement point mp in a connection table 43e in Step S1109. In a case where there is no measurement point my that has not been selected (No in Step S1109), the process is returned to Step S1104. On the other hand, in a case where there is a measurement point my that has not been selected (Yes in Step S1109), the determination unit 54 selects one measurement point my that has not been selected out of the other measurement points my included in the via that includes the selected measurement point mp in Step S1110. Then, the determination unit 54 determines whether or not the type of the element that includes the selected measurement point my is the power consuming pin in Step S1111. In a case where the type of the element is not the power consuming pin (No in Step S1111), the process is returned to Step S1109. On the other hand, in a case where the type of the element is the power consuming pin (Yes in Step S1111), the determination unit 54 removes the measurement point my from the determination table in Step S1112, and the process is returned to Step S1109.

Accordingly, in a case where the connection relation of measurement points is not appropriate in the context of a display such as a case where the path of a voltage drop is not present, the drawing process can be stopped.

For example, in each process described in each embodiment, the whole or a part of the process described as being automatically performed may be performed in a manual manner. In addition, the whole or a part of the process that has been described as being manually performed in each embodiment may be performed in an automatic manner by using a known method.

In addition, in accordance with various loads, the usage status, and the like, the process performed in each step of each process described in each embodiment may be arbitrarily divided in parts or may be put together. Furthermore, any step may be omitted.

Furthermore, in accordance with various loads, the usage status, and the like, the processing sequence in the steps of each process described in each embodiment may be changed.

In addition, each constituent element of each device illustrated in the diagram is a functional and conceptual element and does not necessarily need to be physically configured as illustrated in the diagram. In other words, a specific state of the division or integration of each device is not limited to that illustrated in the diagram, and the whole or a part thereof may be configured to be functionally or physically divided or integrated in an arbitrary unit in accordance with various loads, the usage status, and the like.

Drawing Program

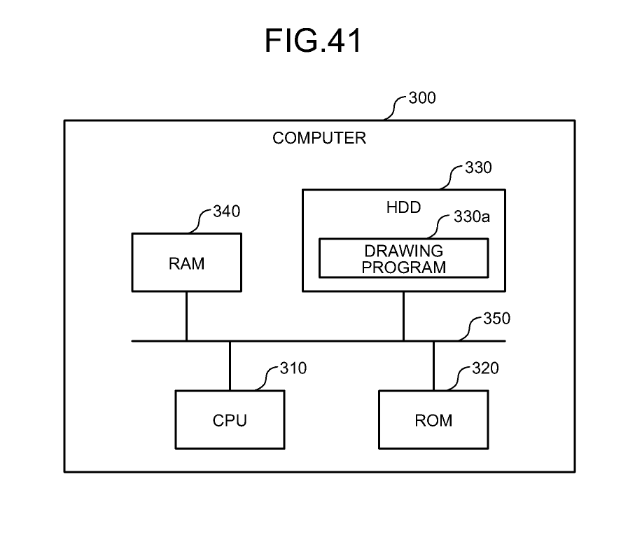

Various kinds of processes performed by the drawing device 10, 30, or 40 described in the above-described embodiment may be realized by executing a program that is prepared in advance using a computer system such as a personal computer or a workstation. Thus, hereinafter, an example of a computer that executes drawing program that has the same function as that of the drawing device 10, 30, or 40 described in the above-described embodiment will be described with reference to FIG. 41. FIG. 41 is a diagram that illustrates the computer that executes the drawing program.

As illustrated in FIG. 41, a computer 300 includes a CPU 310, a ROM 320, an HDD 330, and a RAM 340. The CPU 310, the ROM 320, the HDD 330, and the RAM 340 are interconnected through a bus 350.

In the ROM 320, a basic program such as an OS is stored. In the HDD 330, drawing program 330a, which realizes the same functions as those of the recording unit, the measurement unit, the drawing unit, the display control unit, the determination unit, and the like illustrated in the above-described embodiments is stored in advance. The drawing program 330a may be appropriately separated. In addition, in the HDD 330, first CAD data, second CAD data, a measurement point table, a connection table, image data, and the like are disposed. The first CAD data, the second CAD data, the measurement point table, the connection table, and the image data correspond to the first CAD data 13a, the second CAD data 13b, the measurement point table 13c, the connection tables 13d, 33d, and 43d, and the image data 13e described above.

Then, the CPU 310 reads the drawing program 330a from the HDD 330 and executes the drawing program 330a.

Then, the CPU 310 reads the first CAD data, the second CAD data, the measurement point table, the connection table, the image data, and the like and stores the data and tables in the RAM 340. In addition, the CPU 310 executes the drawing program 330a using the first CAD data, the second CAD data, the measurement point table, the connection table, the image data, and the like that are stored in the RAM 340. it is not necessary to store all data in the RAM 340, but only data used for the processing may be stored in the RAM 340.

Moreover, it is not necessary to store the above-mentioned drawing program in the HDD 330 from the initial stage.

For example, the program is stored in a “portable physical medium” such as a flexible disc (FD), a CD-ROM, a DVD disc, a magneto-optical disk, or an IC card that is inserted into the computer 300. Then, the computer 300 may be configured to read the program from the portable physical medium and execute the program.

Furthermore, the program is stored in “another computer (or a server)” that is connected to the computer 300 through a public circuit, the internet, a LAN, a WAN, or the like. Then, the computer 300 may be configured to read the program from another computer and execute the program.

According to one aspect, the appearance of a voltage drop in the laminated circuit board can be perceived in an easy manner.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A drawing device comprising:
a memory; and
a processor coupled to the memory, wherein the processor executes a process comprising:
measuring voltages of planes of layers in a laminated circuit board; and
drawing the voltages of the planes that are measured on a graph having a voltage set on one axis and having a layer set on the other axis.

2. The drawing device according to claim 1,
wherein the measuring further includes measuring voltages of vias in the laminated circuit board, and
wherein the drawing includes drawing the voltages of the vias that are measured on the graph.

3. The drawing device according to claim 1,
wherein the measuring further includes measuring currents flowing between predetermined portions of the planes, and
wherein the drawing further draws segments having thicknesses or colors corresponding to magnitudes of the currents measured at positions on the graph that correspond to the predetermined portions.

4. The drawing device according to claim 1,
wherein the measuring further includes measuring currents flowing between predetermined portions of the vias, and
wherein the drawing further includes drawing segments having thicknesses or colors corresponding to magnitudes of the currents flowing between predetermined portions of the vias that are measured at positions on the graph that correspond to the predetermined portions.

5. The drawing device according to claim 4, wherein the drawing includes drawing the segments having shapes that indicate directions of the currents flowing between the predetermined portions of the vias at positions on the graph that correspond the predetermined portions.

6. The drawing device according to claim 1, further comprising outputting an error in a case where connection relation of the planes or the vias for which voltages or currents are measured does not satisfy a predetermined condition.

7. A drawing method executed a computer, the drawing method comprising:
measuring voltages of planes of layers in a laminated circuit board, using the computer; and
drawing the measured voltages of the planes on a graph having a voltage set on one axis and having a layer set on the other axis, using the computer.

8. A computer-readable recording medium having stored therein a drawing program causing a computer to execute a process, the process comprising:
measuring voltages of planes of layers in a laminated circuit board; and
drawing the measured voltages of the planes on a graph having a voltage set on one axis and having a layer set on the other axis.
